(19) United States
(12) Patent Application Publication
(10) Pub. No.: US 2026/0033057 A1
(43) Pub. Date: Jan. 29, 2026

(54) Display Apparatus

(71) Applicant: LG Display Co., Ltd., Seoul (KR)

(72) Inventors: Seongsoo Cho, Paju-si (KR); WooSung Kim, Paju-si (KR); Hyunseok Na, Paju-si (KR); SangHak Shin, Paju-si (KR)

(21) Appl. No.: 19/259,500

(22) Filed: Jul. 3, 2025

(30) Foreign Application Priority Data
Jul. 24, 2024 (KR) 10-2024-0098030

(51) Int. Cl. H10H 29/34; H10H 29/37; H10H 29/49; H10H 29/80; H10H 29/854; H10H 29/855

(52) U.S. Cl. CPC H10H 29/34; H10H 29/37; H10H 29/49; H10H 29/854; H10H 29/8552; H10H 29/882

(57) ABSTRACT

A display apparatus is provided, which comprises a substrate including a display area and a non-display area, a pixel driving circuit arranged in the display area of the substrate, an insulating layer on the pixel driving circuit, a bank on the insulating layer, a main light emitting diode provided on the bank while overlapping the bank, and a first optical layer arranged on a side of the main light emitting diode, wherein an entire area of the first optical layer on a plane overlaps the main light emitting diode.

### CROSS-REFERENCE TO RELATED APPLICATION

This application claims the benefit and priority to the Republic of Korea Patent Application No. 10-2024-0098030 filed on Jul. 24, 2024, which is hereby incorporated by reference in its entirety.

### TECHNICAL FIELD

The present disclosure relates to a display apparatus, and particularly to, for example, without limitation, a display apparatus in which the number of redundancy light emitting diodes is reduced.

### DESCRIPTION OF THE RELATED ART

A display apparatus has been applied to various electronic devices such as TVs, mobile phones, laptops, and tablets.

Examples of the display apparatus include an organic light emitting display (OLED) that emits light by itself, and a liquid crystal display (LCD) that require a separate light source.

Recently, a display apparatus including a light emitting diode (LED) has attracted attention as a next-generation display apparatus. Since the light emitting diode is made of an inorganic material rather than an organic material, the display apparatus including a light emitting diode has a faster lighting speed than the liquid crystal display or the organic light emitting display, has excellent light emitting efficiency, and may display an image having high luminance.

### SUMMARY

The present disclosure has been made in view of the above problems and it is an embodiment of the present disclosure to provide a display apparatus in which the number of redundancy light emitting diodes is reduced.

It is another embodiment of the present disclosure to provide a display apparatus in which a manufacturing cost is reduced as the number of redundancy light emitting diodes is reduced.

In addition to the embodiments of the present disclosure as mentioned above, additional aspects and features of the present disclosure will be clearly understood by those skilled in the art from the following description of the present disclosure.

To achieve these and other aspects of the inventive concepts, as embodied and broadly described herein, a display apparatus comprises a substrate including a display area and a non-display area, a pixel driving circuit arranged in the display area of the substrate, an insulating layer on the pixel driving circuit, a main light emitting diode provided over the insulating layer, and a first optical layer arranged on a side of the main light emitting diode, wherein an entire area of the first optical layer on a plane overlaps the main light emitting diode.

The first optical layer may surround the side of the main light emitting diode.

The display apparatus may further comprise a second optical layer arranged on one surface of the first optical layer, wherein the first optical layer may be arranged between the second optical layer and the main light emitting diode.

The first optical layer and the second optical layer may be made of materials different from each other.

The first optical layer may include an organic insulating material, the second optical layer may include the organic insulating material in which fine metal particles are dispersed. The organic insulating material may include siloxane, and the fine metal particles may include titanium dioxide (TiO₂).

The display apparatus may further comprise a bank disposed on the insulating layer, a first electrode provided between the main light emitting diode and the bank, and a signal line arranged on the insulating layer while electrically connecting the first electrode with the pixel driving circuit.

The display apparatus may further comprise a passivation layer on the signal line, wherein the first optical layer may be arranged between the passivation layer and the main light emitting diode.

The first optical layer may be formed by dry etching using the main light emitting diode as a mask.

The display apparatus may further comprise a third optical layer arranged on a side of the second optical layer, a second electrode provided on the main light emitting diode while being electrically connected to the main light emitting diode, a contact electrode provided on the insulating layer while electrically connecting the second electrode with the pixel driving circuit, and a plurality of first connection lines electrically connected to each other through a contact hole in the insulating layer, electrically connecting the contact electrode with the pixel driving circuit, wherein the second electrode may be connected to the contact electrode through a contact hole provided in the third optical layer.

The display apparatus may further comprise a second electrode provided on the main light emitting diode while being electrically connected to the main light emitting diode, and a black matrix arranged on the second electrode, and a fourth optical layer arranged between the second electrode and the black matrix, wherein the black matrix may not overlap the first optical layer.

The display apparatus may further comprise a cover layer arranged on the second electrode, a polarizing layer arranged on the cover layer, and a cover member arranged on the polarizing layer.

The display apparatus may further comprise a pad electrode arranged on the insulating layer in the non-display area, and a plurality of second connection lines electrically connected to each other through a contact hole in the insulating layer, electrically connecting the pad electrode with the pixel driving circuit.

The display apparatus may further comprise an encapsulation layer surrounding the main light emitting diode and disposed between the first optical layer and the side of the main light emitting diode. The encapsulation layer may be a reflective layer.

In accordance with another embodiment of the present disclosure, the above and other aspects may be accomplished by the provision of a display apparatus comprising a display area, a non-display area arranged outside the display area, and a plurality of pixels arranged in the display area and arranged in a first direction, wherein each of the plurality of pixels includes a first subpixel, a second subpixel, and a third subpixel, which are arranged sequentially along the first direction, the first subpixel includes a first main subpixel, the second subpixel includes a second main subpixel, the third subpixel includes a third main subpixel, the first main subpixel and the third main subpixel are arranged in a first row parallel with the first direction, and the second main subpixel is arranged in a second row parallel with the first direction and different from the first row.

The first subpixel may include a first blank subpixel arranged in the same column as the first main subpixel, the second subpixel may include a second blank subpixel arranged in the same column as the second main subpixel, and the third subpixel may include a third blank subpixel arranged in the same column as the third main subpixel.

At least one of the first main subpixel, the second main subpixel, or the third main subpixel may include a main light emitting diode, and at least one of the first blank subpixel, the second blank subpixel, or the third blank subpixel may include a redundancy light emitting diode.

The display apparatus may further comprise a first optical layer arranged on a side of the main light emitting diode, and an entire area of the first optical layer on a plane may overlap the main light emitting diode. The first optical layer may not be arranged on a side of the redundancy light emitting diode.

Based on that the transfer defect occurs in any one of the first main subpixel, the second main subpixel, and the third main subpixel, the redundancy light emitting diode may be arranged in the same column as the subpixel where the transfer defect occurs.

The display apparatus may further comprise a signal line electrically connected to the main light emitting diode and the redundancy light emitting diode and extended in a second direction perpendicular to the first direction.

When the plurality of pixels includes N main subpixels, a sum of the number of the main light emitting diodes and the number of the redundancy light emitting diodes may be N.

The plurality of pixels may include a first pixel and a second pixel, which are arranged in a second direction perpendicular to the first direction, each of the first pixel and the second pixel may include a plurality of main light emitting diodes and further include one second electrode electrically connected to the plurality of main light emitting diodes of the first pixel, and other second electrode electrically connected to the plurality of main light emitting diodes of the second pixel, and the one second electrode and the other second electrode may be spaced apart from each other based on an area between the first pixel and the second pixel.

The non-display area may include a first non-display area surrounding the display area, a bending area extended from one side of the first non-display area, and a second non-display area extended from the bending area and in which a pad portion is arranged, the non-display area may be provided with a plurality of link lines extended from the pad portion of the second non-display area to the bending area and the first non-display area, the display area may be provided with a plurality of driving lines connected to the plurality of link lines, and the plurality of driving lines may be connected to a plurality of pixel driving circuits provided in the display area.

In accordance with yet another aspect of the present disclosure, the above and other aspects may be accomplished by the provision of a display apparatus comprising a plurality of pixels arranged in a display area of a substrate, wherein each of the plurality of pixels includes a first subpixel, a second subpixel, and a third subpixel, which are arranged sequentially along a first direction, wherein the first subpixel includes a first main subpixel, the second subpixel includes a second main subpixel, the third subpixel includes a third main subpixel, wherein the first main subpixel, the second main subpixel and the third main subpixel are arranged in a zigzag shape, wherein, based on that the plurality of pixels include N main subpixels, a sum of the number of light emitting diodes included in the plurality of pixels is N.

It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, that may be included to provide a further understanding of the disclosure and may be incorporated in and constitute a part of the disclosure, illustrate embodiments of the disclosure and together with the description serve to explain various principles of the disclosure.

The above and other aspects, features and other advantages of the present disclosure will be more clearly understood from the following detailed description taken in conjunction with the accompanying drawings, in which:

FIG. 1 is an exploded perspective view illustrating a display apparatus according to an example embodiment of the present disclosure;

FIG. 2 is a plan view illustrating a display apparatus according to an example embodiment of the present disclosure;

FIG. 3 is an enlarged view illustrating a display apparatus according to an example embodiment of the present disclosure;

FIG. 4 is a view illustrating a circuit structure according to an example embodiment of the present disclosure;

FIG. 5 is a plan view illustrating a display apparatus according to an example embodiment of the present disclosure;

FIG. 6A is a plan view illustrating a display apparatus according to an example embodiment of the present disclosure;

FIG. 6B is a plan view illustrating a display apparatus according to another example embodiment of the present disclosure;

FIG. 7 is a plan view illustrating a display apparatus according to an example embodiment of the present disclosure;

FIG. 8 is a cross-sectional view illustrating a display apparatus according to an example embodiment of the present disclosure;

FIG. 9 is a cross-sectional view illustrating a display apparatus according to an example embodiment of the present disclosure;

FIG. 10 is a process plan view illustrating a repair process of a light emitting diode according to an example embodiment of the present disclosure;

FIGS. 11A to 11H are process plan views illustrating a repair process of a light emitting diode according to an example embodiment of the present disclosure; and

FIGS. 12 to 15 are views illustrating an apparatus to which a display apparatus according to an example embodiment of the present disclosure is applied.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTION

Reference will now be made in detail to embodiments of the present disclosure, examples of which may be illustrated in the accompanying drawings. In the following description, when a detailed description of well-known functions or configurations related to this document is determined to unnecessarily cloud a gist of the inventive concept, the detailed description thereof will be omitted. The progression of processing steps and/or operations described is an example; however, the sequence of steps and/or operations is not limited to that set forth herein and may be changed as is known in the art, with the exception of steps and/or operations necessarily occurring in a particular order. Like reference numerals designate like elements throughout. Names of the respective elements used in the following explanations may be selected only for convenience of writing the specification and may be thus different from those used in actual products.

Advantages and features of the present disclosure and implementation methods thereof will be clarified through following example embodiments described with reference to the accompanying drawings. The present disclosure may, however, be embodied in different forms and should not be construed as limited to the example embodiments set forth herein. Rather, these example embodiments are provided so that this disclosure will be thorough and complete and will fully convey the scope of the present disclosure to those skilled in the art. Further, the present disclosure is only defined by scopes of claims.

A shape, a size, a ratio, an angle and a number disclosed in the drawings for describing various example embodiments of the present disclosure are merely an example and thus, the present disclosure is not limited to the illustrated details. Like reference numerals refer to like elements throughout the specification. In the following description, when the detailed description of the relevant known function or configuration is determined to unnecessarily obscure the important point of the present disclosure, the detailed description will be omitted.

In a case where ‘comprise’, ‘have’ and ‘include’ described in the present disclosure are used, another portion may be added unless a more limiting term such as ‘only˜’ is used. The terms of a singular form may include plural forms unless referred to the contrary. Any implementation described herein as an “example” is not necessarily to be construed as preferred or advantageous over other implementations.

In construing an element, the element is construed as including an error range or tolerance range although there is no explicit description of such an error or tolerance range.

In describing a position relationship, for example, when the position relationship between two portions is described as ‘on˜’, ‘above˜’, ‘below˜’ and ‘next to˜’, one or more portions may be arranged between the two portions unless a more limiting term, such as ‘just’ or ‘direct’ is used.

In describing a position relationship, for example, when the position relationship is described as ‘upon˜’, ‘above˜’, ‘below˜’, and ‘next to˜’, one or more portions may be arranged between two other portions unless a more limiting term, such as ‘just’ or ‘direct’ is used. Spatially relative terms such as “below”, “beneath”, “lower”, “above”, and “upper” may be used herein to easily describe a relationship of one element or elements to another element or elements as illustrated in the figures. It will be understood that these terms are intended to encompass different orientations of the device in addition to the orientation depicted in the figures. For example, if the device illustrated in the figure is reversed, the device described to be arranged “below”, or “beneath” another device may be arranged “above” another device. Therefore, an exemplary term “below or beneath” may include “below or beneath” and “above” orientations. Likewise, an exemplary term “above” or “on” may include “above” and “below or beneath” orientations. Furthermore, the terms “left,” “right,” “top,” “bottom, “downward,” “upward,” “upper,” “lower,” and the like refer to an arbitrary frame of reference.

In describing a temporal relationship, for example, when the temporal order is described as “after,” “subsequent,” “next,” and “before,” a case which is not continuous may be included, unless a more limiting term, such as “just” or “direct” is used.

It will be understood that, although the terms “first,” “second,” “A,” “B,” “(a),” and “(b),” etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. Also, when an element or layer is described as being “connected,” “coupled,” or “adhered” to another element or layer, the element or layer can not only be directly connected, or adhered to that other element or layer, but also be indirectly connected, or adhered to that other another element or layer with one or more intervening elements or layers “disposed” between the elements or layers, unless otherwise specified.

It should be understood that the term “at least one” includes all combinations related with any one item. For example, “at least one among a first element, a second element and a third element” may include all combinations of two or more elements selected from the first, second and third elements as well as each element of the first, second and third elements.

Features of various embodiments of the present disclosure may be partially or overall coupled to or combined with each other and may be variously inter-operated with each other and driven technically as those skilled in the art can sufficiently understand. The embodiments of the present disclosure may be carried out independently from each other or may be carried out together in a co-dependent relationship.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

In adding reference numerals to elements of each drawing describing embodiments of the present disclosure, the same elements may have the same reference numerals as possible even though they are shown on different drawings.

Hereinafter, example embodiments of the present disclosure will be described in detail with reference to the accompanying drawings. All the components of each display apparatus according to all embodiments of the present disclosure are operatively coupled and configured.

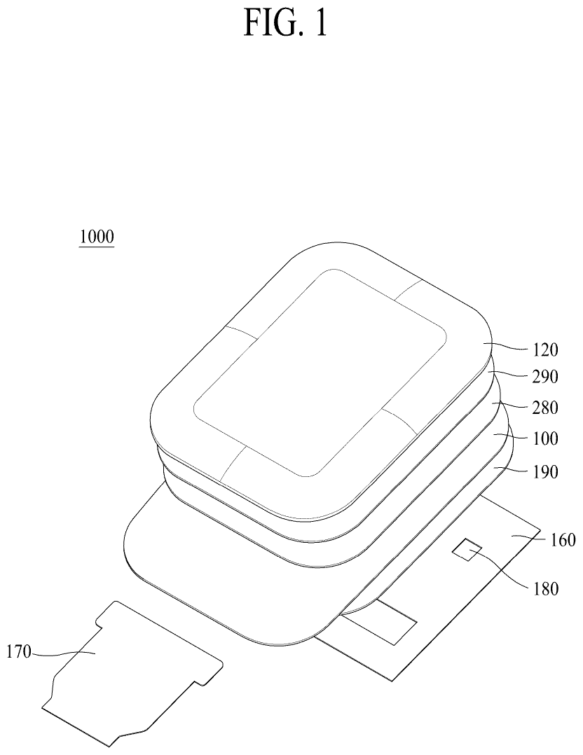

FIG. 1 is a perspective view illustrating a display apparatus 1000 according to an embodiment of the present disclosure.

Referring to FIG. 1, the display apparatus 1000 according to an embodiment of the present disclosure may include a display panel 100, a polarizing layer 280, an adhesive layer 290, a cover member 120, a support substrate 190, a flexible circuit board 170, and a printed circuit board 160.

The display panel 100 may implement information, video, and/or images provided to a user.

The polarizing layer 280 may be arranged on the display panel 100. The polarizing layer 280 may prevent or reduce light generated from an external light source from entering the display panel 100 and affecting a light emitting diode or the like.

The adhesive layer 290 may attach the cover member 120 to the display panel 100. The adhesive layer 290 may be arranged between the polarizing layer 280 and the cover member 120 to attach the cover member 120 to the polarizing layer 280. The adhesive layer 290 may include an optically clear adhesive (OCA), an optically clear resin (OCR), a pressure sensitive adhesive (PSA) or the like, but the embodiments of the present disclosure are not limited thereto.

The cover member 120 may be arranged on the polarizing layer 280. The cover member 120 may be arranged on the adhesive layer 290. The cover member 120 may be a member for protecting the display panel 100. The cover member 120 may be made of a transparent material.

The support substrate 190 may be arranged between the display panel 100 and the printed circuit board 160. The support substrate 190 may reinforce rigidity of the display panel 100. The support substrate 190 may be a back plate, but the embodiments of the present disclosure are not limited thereto.

The flexible circuit board 170 and the printed circuit board 160 may be arranged below the display panel 100. The flexible circuit board 170 and the printed circuit board 160 may be arranged on at least one edge of the display panel 100, but the embodiments of the present disclosure are not limited thereto. One side of the flexible circuit board 170 may be attached to the display panel 100, and the other side thereof may be attached to the printed circuit board 160, but the embodiments of the present disclosure are not limited thereto. The flexible circuit board 170 may be a flexible film, but the embodiments of the present disclosure are not limited thereto.

The printed circuit board 160 may include at least one hole 180, but the embodiments of the present disclosure are not limited thereto. An internal component that senses ambient light or temperature and that may be provided to a plurality of sensors may be arranged in an area corresponding to at least one hole 180. For example, the internal component may include an ambient light sensor (ALS) or a temperature sensor, but the embodiments of the present disclosure are not limited thereto. For example, the hole 180 may be a transmissive hole, etc., but the embodiments of the present disclosure are not limited thereto.

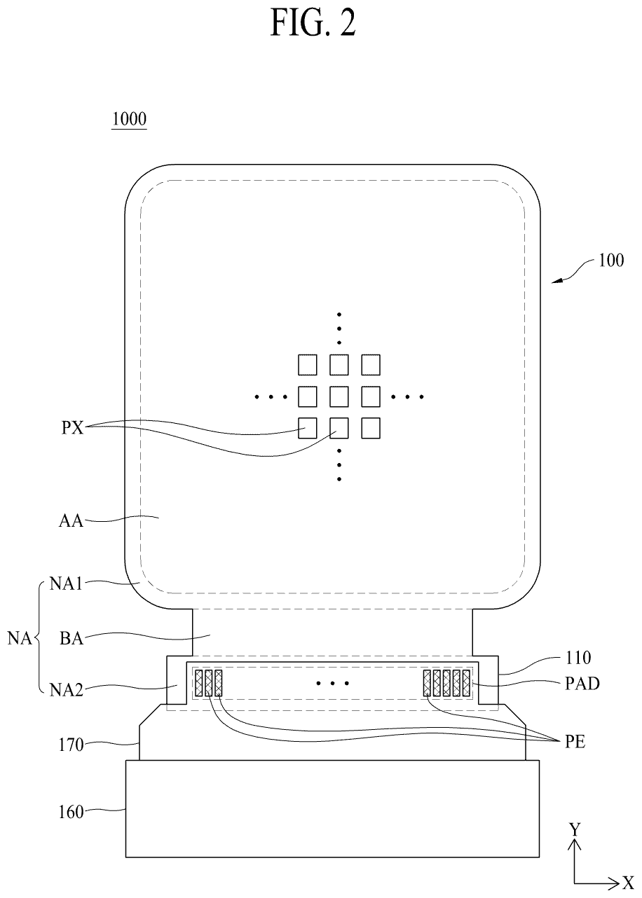

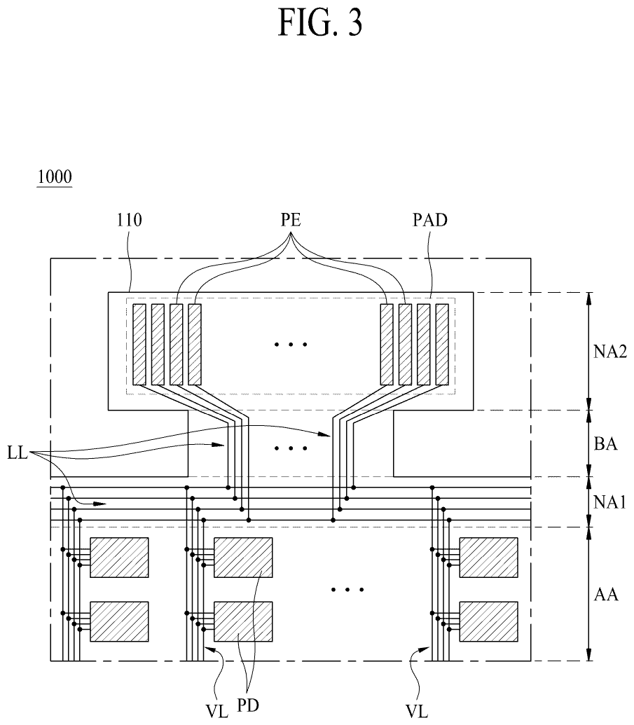

FIG. 2 is a plan view illustrating the display apparatus 1000 according to an embodiment of the present disclosure, and FIG. 3 is an enlarged view illustrating the display apparatus 1000 according to an embodiment of the present disclosure.

Referring to FIGS. 2 and 3, the display apparatus 1000 may include a display panel 100, a flexible circuit board 170, and a printed circuit board 160.

The display panel 100 may include a substrate 110. The substrate 110 may be a member that supports other components of the display apparatus 1000. The substrate 110 may be made of an insulating material. For example, the substrate 110 may be made of glass or resin. Also, the substrate 110 may be made of a material having flexibility. For example, the substrate 110 may be made of a plastic material having flexibility, such as polyimide (PI), but the embodiments of the present disclosure are not limited thereto. The substrate 110 may include glass, plastic, or a flexible polymer film. For example, the flexible polymer film may be made of any one of polyethylene terephthalate (PET), polycarbonate (PC), acrylonitrile-butadiene-styrene copolymer (ABS), polymethyl methacrylate (PMMA), polyethylene naphthalate (PEN), polyether sulfone (PES), cyclic olefin copolymer (COC), triacetylcellulose (TAC) film, polyvinyl alcohol (PVA) film, polyimide (PI) film, and polystyrene (PS), which is an example and is not necessarily limited thereto.

For example, the display panel 100 may include a display area AA and a non-display area NA adjacent to the display area AA. For example, the substrate 110 may include a display area AA and a non-display area NA. The display area AA and the non-display area NA are not limited to the substrate 110 but may be described throughout the display apparatus 1000. The non-display area NA may be disposed to surround the display area AA.

The display area AA may be an area in which an image is displayed. The display area AA may include a plurality of pixels PX. Each of the plurality of pixels PX may include a plurality of subpixels. A plurality of light emitting diodes may be arranged in each of the plurality of subpixels. The plurality of light emitting diodes may be configured to be different depending on a type of the display apparatus 1000. For example, when the display apparatus 1000 is an inorganic light emitting display apparatus, the light emitting diode may be a light emitting diode (LED), a micro light emitting diode (Micro-LED), or a mini-light emitting diode (Mini LED), but the embodiments of the present disclosure are not limited thereto.

The display area AA may be configured in various shapes depending on the design of the display apparatus 1000. For example, the display area AA may be configured in a rectangular shape having four rounded corners, but the embodiments of the present disclosure are not limited thereto. In another example, the display area AA may be configured in a rectangular shape having four right angled corners or a rounded or circular shape, but the embodiments of the present disclosure are not limited thereto.

Referring to FIG. 3, a plurality of pixel driving circuits PD may be arranged in the display area AA. The plurality of pixel driving circuits PD may be circuits for driving light emitting diodes of the plurality of subpixels. Each of the plurality of pixel driving circuits PD includes a plurality of transistors including driving transistors, and a capacitor, and may control light emitting operations of the plurality of light emitting diodes by supplying a control signal, power, and driving current to the light emitting diodes of the plurality of subpixels. For example, the pixel driving circuit PD may include a power line, and a signal line for controlling light emission on/off and/or light emission time of the light emitting diode. For example, the plurality of pixel driving circuits PD may be pixel drivers manufactured on a semiconductor substrate using a manufacturing process of a metal-oxide-silicon field effect transistor (MOSFET), but the embodiments of the present disclosure are not limited thereto. The pixel driver includes a plurality of pixel driving circuits PD and may drive a plurality of subpixels.

The non-display area NA may be an area in which no image is displayed. Various lines, circuits, and the like for driving the plurality of pixels PX of the display area AA may be arranged in the non-display area NA. For example, various lines and driving circuits may be packaged in the non-display area NA, and a pad portion PAD connected to an integrated circuit and a printed circuit may be arranged, but the embodiments of the present disclosure are not limited thereto.

For example, the driving circuit may be a data driving circuit and/or a gate driving circuit, but the embodiments of the present disclosure are not limited thereto. Lines to which a control signal for controlling the driving circuits is supplied may be arranged in the non-display area NA. For example, the control signal may include various timing signals including a clock signal, an input data enable signal, and synchronization signals, but the embodiments of the present disclosure are not limited thereto. The control signal may be received through the pad portion PAD. For example, link lines LL for transmitting a signal may be arranged in the non-display area NA. For example, the driving component such as the flexible circuit board 170 and the printed circuit board 160 may be connected to the pad portion PAD.

According to an embodiment of the present disclosure, the non-display area NA may include a first non-display area NA1, a bending area BA, and a second non-display area NA2. For example, the first non-display area NA1 may be an area surrounding at least a portion of the display area AA. The bending area BA may be an area extended from at least one of a plurality of sides of the first non-display area NA1 and may be a bendable area. The second non-display area NA2 is an area extended from the bending area BA, and the pad portion PAD may be arranged in the second non-display area. For example, the bending area BA may be in a bent state, and the remaining area of the substrate 110 other than the bending area BA may be in a flat state. In this case, as the bending area BA is bent, the second non-display area NA2 may be positioned on a rear surface of the display area AA, but the embodiments of the present disclosure are not limited thereto.

The plurality of link lines LL may be arranged in the non-display area NA. The plurality of link lines LL may be lines for transmitting various signals from one or more flexible circuit boards (or flexible films) 170 and the printed circuit board 160 to the display area AA. The plurality of link lines LL may be extended from a plurality of pad electrodes PE of the second non-display area NA2 toward the bending area BA and the first non-display area NA1 and thus be electrically connected to a plurality of driving lines VL of the display area AA. The plurality of pixel driving circuits PD may be driven by receiving signals from one or more flexible circuit boards (or flexible films) 170 and the printed circuit board 160 through the driving line VL in the display area AA and the link line LL in the non-display area NA.

For example, the plurality of driving lines VL may be lines for transmitting a signal output from the flexible circuit board (or the flexible film) 170 and the printed circuit board 160 to the plurality of pixel driving circuits PD together with the plurality of link lines LL. The plurality of driving lines VL may be arranged in the display area AA and electrically connected to each of the plurality of pixel driving circuits PD. The plurality of driving lines VL may be extended from the display area AA toward the non-display area NA, and may be electrically connected to the plurality of link lines LL. Accordingly, the signal output from the flexible circuit board (or the flexible film) 170 and the printed circuit board 160 may be transmitted to each of the plurality of pixel driving circuits PD through the plurality of link lines LL and the plurality of driving lines VL.

As the bending area BA is bent, a portion of the plurality of link lines LL may also be bent. Stress is concentrated on a portion of the bent link line LL, and thus, cracks may occur in the link line LL. Accordingly, the plurality of link lines LL may be made of a conductive material having excellent flexibility in order to reduce cracks when the bending area BA is bent. For example, the plurality of link lines LL may be made of a conductive material having excellent flexibility, such as gold (Au), silver (Ag) and aluminum (Al), but the embodiments of the present disclosure are not limited thereto. Also, the plurality of link lines LL may be made of one of various conductive materials used in the display area AA. For example, the plurality of link lines LL may be made of molybdenum (Mo), chromium (Cr), titanium (Ti), nickel (Ni), neodymium (Nd), copper (Cu), an alloy of silver (Ag) and magnesium (Mg), or their alloy, but the embodiments of the present disclosure are not limited thereto. The plurality of link lines LL may be configured in a multi-layered structure including various conductive materials. For example, the plurality of link lines LL may be configured in a triple layer structure of titanium (Ti), aluminum (Al) and titanium (Ti), but the embodiments of the present disclosure are not limited thereto.

The plurality of link lines LL may be configured in various shapes to reduce stress. At least a portion of the plurality of link lines LL arranged on the bending area BA may be extended in the same direction as the extended direction of the bending area BA or may be extended in a direction different from the extended direction of the bending area BA to reduce stress. For example, when the bending area BA extends in one direction from the first non-display area NA1 toward the second non-display area NA2, at least a portion of the link line LL arranged on the bending area BA may be extended in a direction inclined with respect to the one direction. In another example, at least a portion of the plurality of link lines LL may be configured in various shapes. For example, at least a portion of the plurality of link lines LL arranged on the bending area BA may have a shape in which a conductive pattern having at least one of a diamond shape, a rhombus shape, a trapezoidal shape, a triangular wave shape, a sawtooth wave shape, a sinusoidal shape, a circular shape or an omega (Ω) shape is repeatedly arranged, but the embodiments of the present disclosure are not limited thereto. Therefore, in order to minimize or reduce the stress concentrated on the plurality of link lines LL and the resulting cracks, the shape of the plurality of link lines LL may be formed in various shapes including the above-described shape, but the embodiments of the present disclosure are not limited thereto.

According to the present disclosure, a width of the second non-display area NA2 in which a plurality of pad electrodes PE are arranged may be wider than a width of the bending area BA in which only the plurality of link lines LL are arranged. Also, the width of the display area AA in which a plurality of subpixels are arranged may be wider than the width of the bending area BA in which only the plurality of link lines LL are arranged. Although the width of the bending area BA is shown to be narrower than that of other areas of the substrate 110, the shape of the substrate 110 including the bending area BA is exemplary, and the embodiments of the present disclosure are not limited thereto.

The pad portion PAD including a plurality of pad electrodes PE may be arranged in the second non-display area NA2. Driving components including one or more flexible circuit boards (or flexible films) 170 and a printed circuit board 160 may be attached to or bonded to the pad portion PAD. The plurality of pad electrodes PE of the pad portion PAD are electrically connected to one or more flexible circuit boards (or flexible films) 170 and may transfer various signals (or power sources) received from the printed circuit board 160 and the flexible circuit board (or the flexible film) 170 to the plurality of pixel driving circuits PD of the display area AA.

The flexible circuit board (or the flexible film) 170 may be a film in which various components are arranged on a flexible base film. For example, a driving integrated circuit (IC) such as a gate driver IC or a data driver IC may be arranged in the flexible circuit board (or the flexible film) 170, but the embodiments of the present disclosure are not limited thereto. The driving IC may be a component that processes data and a driving signal for displaying an image. The driving IC may be arranged by a method such as a chip on glass (COG) or a chip on film (COF) or a tape carrier package (TCP) depending on a packaging method, but the embodiments of the present disclosure are not limited thereto. The flexible circuit board (or the flexible film) 170 may be attached or bonded onto the plurality of pad electrodes PE through a conductive adhesive layer, but the embodiments of the present disclosure are not limited thereto.

The printed circuit board 160 may be a component electrically connected to one or more flexible circuit boards (or flexible films) 170, supplying signals to the driving IC. The printed circuit board 160 may be arranged at one side of the flexible circuit board (or the flexible film) 170, and thus may be electrically connected to the flexible circuit board (or the flexible film) 170. Various components for supplying various signals to the driving IC may be arranged in the printed circuit board 160. For example, various components, such as a timing controller, a power supply unit, a memory, or a processor, may be arranged in the printed circuit board 160. For example, the printed circuit board 160 may include a power management integrated circuit (PMIC), but the embodiments of the present disclosure are not limited thereto.

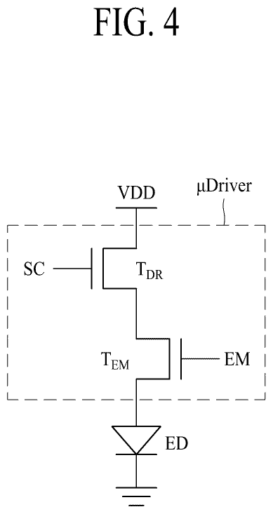

FIG. 4 is a view illustrating a circuit structure according to an embodiment of the present disclosure.

FIG. 4 illustrates that one light emitting diode ED is connected to a micro-driver μDriver, but is not limited thereto. For example, eight light emitting diodes ED may be connected to one micro-driver μDriver. In another example, 16 light emitting diodes ED may be connected to one micro-driver μDriver, 32 light emitting diodes ED or 64 light emitting diodes ED may be connected to one micro-driver μDriver at the same time. The light emitting diode ED may be a micro light emitting diode μLED.

One micro-driver may include a driving transistor TDR and a light emitting transistor TEM, but the embodiments of the present disclosure are not limited thereto.

For example, a high potential power supply voltage VDD may be applied to a first electrode of the driving transistor T_{DR}, a first electrode of the light emitting transistor T_{EM} may be connected to a second electrode of the driving transistor T_{DR}, and a scan signal SC may be applied to a gate electrode of the driving transistor T_{DR}. The scan signal SC applied to the gate electrode of the driving transistor T_{DR} is a direct current power source, and a fixed reference voltage Vref may be applied to each frame, but the embodiments of the present disclosure are not limited thereto.

A second electrode of the driving transistor T_{DR} may be connected to the first electrode of the light emitting transistor T_{EM}, the light emitting diode ED may be connected to a second electrode of the light emitting transistor T_{EM}, and a light emitting signal EM may be applied to a gate electrode of the light emitting transistor T_{EM}. The light emitting signal EM applied to the gate electrode of the light emitting transistor T_{EM} may be a pulse width modulation signal that changes every frame, but the embodiments of the present disclosure are not limited thereto.

A first electrode of the light emitting diode ED may be connected to the second electrode of the light emitting transistor T_{EM}, and a second electrode of the light emitting diode ED may be connected to the ground. For example, the first electrode of the light emitting diode ED may be an anode electrode, and the second electrode of the light emitting diode ED may be a cathode electrode, but the embodiments of the present disclosure are not limited thereto.

Each of the driving transistor T_{DR} and the light emitting transistor T_{EM} may be an n-type transistor or a p-type transistor.

The driving transistor T_{DR} may be turned on by the scan signal SC applied from a timing controller T-CON in the micro-driver μDriver, and the light emitting transistor T_{EM} may be turned on by the light emitting signal EM. As a result, the driving current is applied to the light emitting diode ED via the driving transistor T_{DR} and the light emitting transistor T_{EM} by the high potential power voltage VDD applied to the first electrode of the driving transistor T_{DR}, and thus the light emitting diode ED may emit light.

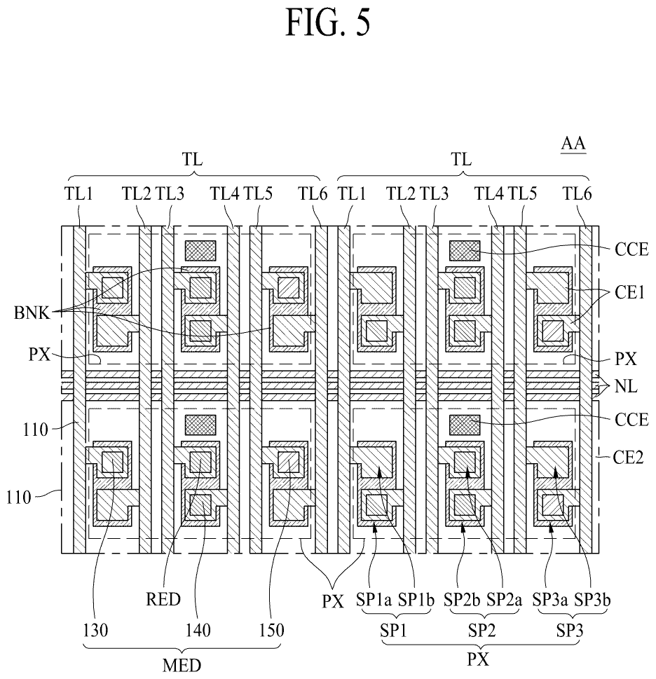

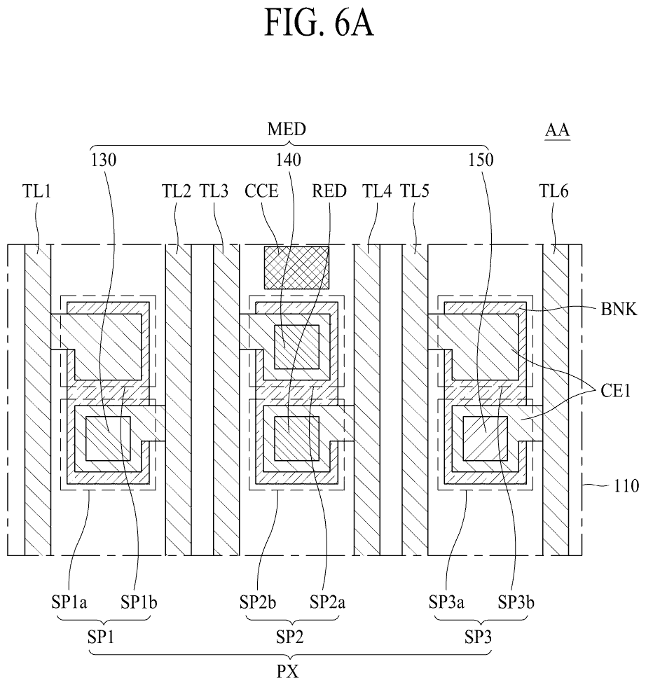

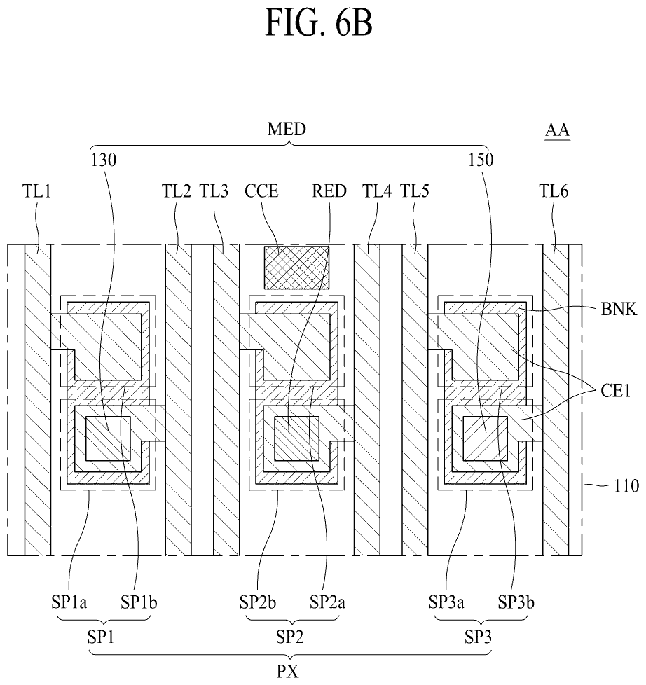

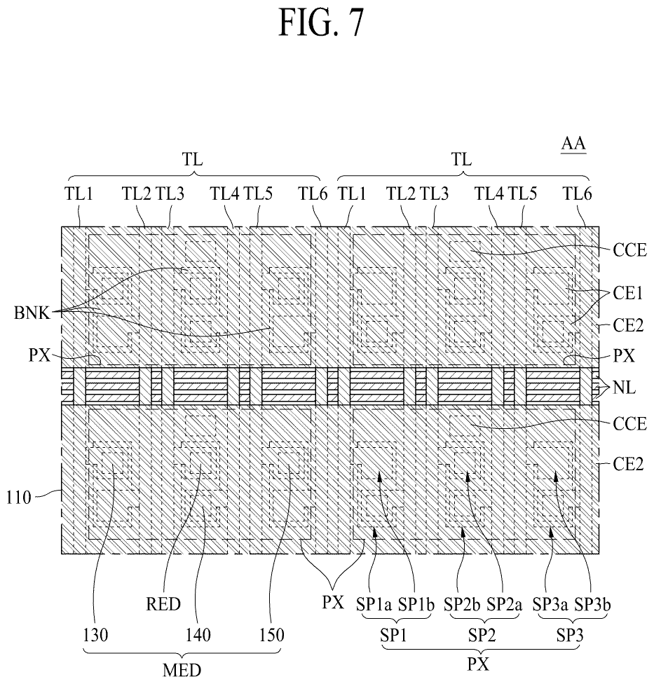

FIGS. 5 to 7 are plan views illustrating a display apparatus according to an embodiment of the present disclosure. For example, FIG. 5 is an enlarged plan view of a display area including a plurality of pixels according to an embodiment of the present disclosure. For example, FIGS. 6A and 6B are enlarged plan views of a display area including one pixel according to an embodiment of the present disclosure. For example, FIG. 7 is an enlarged plan view of a display area including a plurality of pixels according to an embodiment of the present disclosure. In FIGS. 5, 6A, and 6B, a plurality of signal lines TL, a plurality of communication lines NL, a plurality of first electrodes CE1, a plurality of banks BNK, and a plurality of main light emitting diodes are illustrated, but the embodiments of the present disclosure are not limited thereto. FIG. 7 is an enlarged plan view in which a plurality of second electrodes CE2 are additionally arranged in FIG. 5, and for convenience, an area overlapping the second electrode CE2 is indicated by a dotted line.

Referring to FIGS. 5 to 7, the plurality of pixels PX including a plurality of subpixels may be arranged in the display area AA. Each of the plurality of subpixels includes a main light emitting diode MED and may independently emit light. The plurality of subpixels may constitute a plurality of rows and a plurality of columns, and may be arranged in a matrix form, but the embodiments of the present disclosure are not limited thereto.

The plurality of subpixels may include a first subpixel SP1, a second subpixel SP2, and a third subpixel SP3. For example, any one of the first subpixel SP1, the second subpixel SP2, and the third subpixel SP3 may be a red subpixel, another one thereof may be a green subpixel, and the rest one may be a blue subpixel. Types of a plurality of subpixels are exemplary, and the embodiments of the present disclosure are not limited thereto. For example, the plurality of subpixels may include a fourth subpixel which is a white subpixel.

According to an embodiment of the present disclosure, the first subpixel SP1 may include a first main subpixel SPla and a first blank subpixel SP1b. The second subpixel SP2 may include a second main subpixel SP2a and a second blank subpixel SP2b. The third subpixel SP3 may include a third main subpixel SP3a and a third blank subpixel SP3b. However, the embodiments of the present disclosure are not limited to these examples.

According to an embodiment of the present disclosure, at least one of the first main subpixel SPla, the second main subpixel SP2a or the third main subpixel SP3a includes a main light emitting diode MED.

In detail, the first main subpixel SPla may include a first main light emitting diode 130, the second main subpixel SP2a may include a second main light emitting diode 140, and the third main subpixel SP3a may include a third main light emitting diode 150.

In FIG. 6A, the first main subpixel SPla, the second main subpixel SP2a, and the third main subpixel SP3a include the first main light emitting diode 130, the second main light emitting diode 140, and the third main light emitting diode 150, respectively.

In more detail, FIG. 6A illustrates a case that the second main light emitting diode 140 arranged in the second main subpixel SP2a is transferred, but the second main light emitting diode 140 itself is defective.

According to an embodiment of the present disclosure, at least one of the first subpixel SP1, the second subpixel SP2, or the third subpixel SP3 includes a redundancy light emitting diode RED.

In detail, at least one of the first blank subpixel SP1b, the second blank subpixel SP2b, or the third blank subpixel SP3b includes the redundancy light emitting diode RED.

For example, in FIG. 6A, the second blank subpixel SP2b of the second subpixel SP2 includes the redundancy light emitting diode RED, but an embodiment of the present disclosure is not limited thereto.

Two or more of the first blank subpixel SP1b, the second blank subpixel SP2b, and the third blank subpixel SP3b may include the redundancy light emitting diode RED.

Various defects may occur in the process of transferring a plurality of main light emitting diodes MED having a fine size from a wafer to the substrate 110. For example, a non-transfer defect in which the main light emitting diode MED is not transferred may occur in some subpixels, and a defect in which the main light emitting diode MED is transferred out of its proper position due to an alignment error may occur in other some subpixels. In another example, the transfer process has been performed normally, but the transferred main light emitting diode MED itself may be defective.

For example, in FIG. 6B, the first main subpixel SPla and the third main subpixel SP3a include the first main light emitting diode 130 and the third main light emitting diode 150, respectively. In detail, the second main subpixel SP2a does not include the second main light emitting diode 140.

FIG. 6B illustrates a case that a non-transfer defect of the second main light emitting diode 140 occurs in the second main subpixel SP2a.

At this time, light inspection may be performed for the plurality of main light emitting diodes MED, and the redundancy light emitting diode RED may be arranged in the same column of the main light emitting diode MED that has finally been determined to be defective.

In detail, the main light emitting diode MED determined to be defective is not used, and the redundancy light emitting diode RED arranged in the same column may be used. In other words, the redundancy light emitting diode RED is a light emitting diode additionally arranged in the same subpixel after a defect of the main light emitting diode MED is checked.

In more detail, when a transfer defect occurs in any one of the first main subpixel SPla, the second main subpixel SP2a, and the third main subpixel SP3a, the redundancy light emitting diode RED is arranged in the same column as the subpixel in which the transfer defect occurs. For example, referring to FIGS. 6A and 6B, the redundancy light emitting diode RED is arranged in the same column as the second main subpixel SP2a in which the defect occurs.

Generally, when N main light emitting diodes MED are to be formed in the plurality of pixels PX, N redundancy light emitting diodes RED are additionally transferred in preparation for a defect in any one of the N main light emitting diodes MED.

However, when N redundancy light emitting diodes RED are additionally transferred to form N main light emitting diodes MED like the related art, the number of redundancy light emitting diodes RED transferred per product increases, resulting in an increase in overall cost.

According to an embodiment of the present disclosure, an area of a blank subpixel may be provided in an area in which N redundancy light emitting diodes RED are to be formed. In this case, the blank subpixel means an area in which the main light emitting diode MED is not transferred.

For example, referring to FIG. 6A, the first subpixel SP1, the second subpixel SP2, and the third subpixel SP3 include a first blank subpixel SP1b, a second blank subpixel SP2b, and a third blank subpixel SP3b, respectively.

For example, when the plurality of pixels PX include N main subpixels, the sum of the number of main light emitting diodes MED and the number of redundancy light emitting diodes RED is N, wherein the main light emitting diodes MED and the redundancy light emitting diodes RED are electrically connected to the signal line TL. In detail, when the plurality of pixels PX include N main subpixels and N blank subpixels, the sum of the number of main light emitting diodes MED and the number of redundancy light emitting diodes RED is N, wherein the main light emitting diodes MED and the redundancy light emitting diodes RED are electrically connected to the signal line TL.

The plurality of subpixels constituting one pixel PX may be variously arranged. For example, in one pixel PX, the first main subpixel SPla and the first blank subpixel SP1b may be arranged in the same column, the second main subpixel SP2a and the second blank subpixel SP2b may be arranged in the same column, and the third main subpixel SP3a and the third blank subpixel SP3b may be arranged in the same column. The first subpixel SP1, the second subpixel SP2, and the third subpixel SP3 may be arranged in the same row. The number and arrangement of the plurality of subpixels constituting one pixel PX are exemplary, and the embodiments of the present disclosure are not limited thereto.

In other words, referring to FIG. 6A, the first main subpixel SPla and the first blank subpixel SP1b are arranged along the second direction Y, the second main subpixel SP2a and the second blank subpixel SP2b are arranged along the second direction Y, and the third main subpixel SP3a and the third blank subpixel SP3b are arranged along the second direction Y. The first subpixel SP1, the second subpixel SP2, and the third subpixel SP3 are arranged in this order along the first direction X.

According to an embodiment of the present disclosure, the first main subpixel SPla of the first subpixel SP1 and the third main subpixel SP3a of the third subpixel SP3 are arranged in a first row parallel with the first direction X, and the second main subpixel SP2a of the second subpixel SP2 is arranged in a second row parallel with the first direction X and different from the first row. In this case, the first row and the second row do not meet.

In detail, FIG. 6A illustrates that the first main subpixel SPla of the first subpixel SP1, the second main subpixel SP2a of the second subpixel SP2, and the third main subpixel SP3a of the third subpixel SP3 are arranged in a zigzag shape.

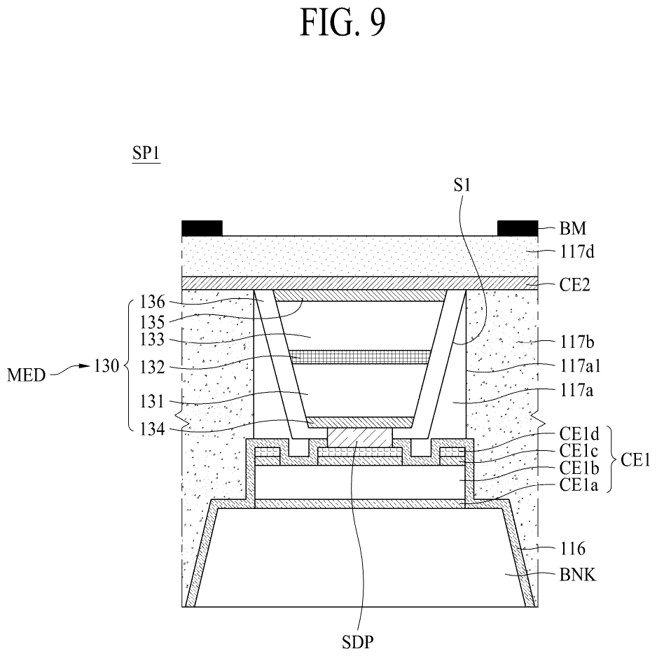

The plurality of signal lines TL may be arranged in an area between the plurality of subpixels. The plurality of signal lines TL may be extended in a column direction between the plurality of subpixels. The plurality of signal lines TL may be lines that transmit an anode voltage from the pixel driving circuit (PD of FIG. 3) to the plurality of subpixels. For example, the plurality of signal lines TL may be electrically connected to the plurality of pixel driving circuits (PD of FIG. 3) and the first electrode CE1 of the plurality of subpixels. The anode voltage output from the pixel driving circuit (PD of FIG. 3) may be transmitted to the first electrode CE1 of the plurality of subpixels through the plurality of signal lines TL. For example, the first electrode CE1 may be an electrode electrically connected to an anode electrode (134 of FIG. 9) of the main light emitting diode MED and the redundancy light emitting diode RED. Accordingly, the anode voltage from the signal line TL may be transmitted to the anode electrode (134 of FIG. 9) of the main light emitting diode MED and the redundancy light emitting diode RED through the first electrode CE1.

Therefore, instead of forming a plurality of transistors and a storage capacitor in each of the plurality of subpixels, a structure of the display apparatus 1000 may be simplified using the pixel driving circuit (PD of FIG. 3) in which the plurality of pixel circuits are integrated. Also, as the circuits arranged in the plurality of subpixels is integrated in one pixel driving circuit (PD of FIG. 3), low power driving of high efficiency may be possible.

The plurality of signal lines TL may include a first signal line TL1, a second signal line TL2, a third signal line TL3, a fourth signal line TL4, a fifth signal line TL5, and a sixth signal line TL6. Each of the first signal line TL1 and the second signal line TL2 may be electrically connected to each of the first main subpixel SPla and the first blank subpixel SP1b of the first subpixel SP1. Each of the third signal line TL3 and the fourth signal line TL4 may be electrically connected to each of the second main subpixel SP2a and the second blank subpixel SP2b of the second subpixel SP2. Each of the fifth signal line TL5 and the sixth signal line TL6 may be electrically connected to each of the third main subpixel SP3a and the third blank subpixel SP3b of the third subpixel SP3.

The first signal line TL1 may be arranged at one side of the first subpixel SP1, and the second signal line TL2 may be arranged at another side of the first subpixel SP1. The second signal line TL2 may be electrically connected to the first electrode CE1 of the first main subpixel SP1a among the first subpixels SP1. The first signal line TL1 may be electrically connected to the first electrode CE1 of the first blank subpixel SP1b of the first subpixel SP1.

The third signal line TL3 may be arranged at one side of the second subpixel SP2, and the fourth signal line TL4 may be arranged at another side of the second subpixel SP2. For example, the third signal line TL3 may be arranged adjacent to the second signal line TL2. The third signal line TL3 may be electrically connected to the first electrode CE1 of the second main subpixel SP2a of the second subpixel SP2. The fourth signal line TL4 may be electrically connected to the first electrode CE1 of the second blank subpixel SP2b of the second subpixel SP2

The fifth signal line TL5 may be arranged on one side of the third subpixel SP3, and the sixth signal line TL6 may be arranged on another side of a pair of third subpixels SP3. For example, the fifth signal line TL5 may be arranged adjacent to the fourth signal line TL4. The sixth signal line TL6 may be arranged adjacent to the first signal line TL1 connected to the adjacent pixel PX. The sixth signal line TL6 may be electrically connected to the first electrode CE1 of the third main subpixel SP3a of the third subpixel SP3. The fifth signal line TL5 may be electrically connected to the first electrode CE1 of the third blank subpixel SP3b of the third subpixel SP3.

The plurality of signal lines TL may be made of a conductive material. For example, the plurality of signal lines TL may be made of a conductive material such as titanium (Ti), aluminum (Al), copper (Cu), molybdenum (Mo), nickel (Ni), chromium (Cr), indium tin oxide (ITO), indium zinc oxide (IZO) and indium gallium zinc oxide (IGZO), but the embodiments of the present disclosure are not limited thereto. In another example, the plurality of signal lines TL may be formed of a multi-layered structure of a conductive material. For example, the plurality of signal lines TL may be formed of a multi-layered structure of titanium (Ti)/aluminum (Al)/titanium (Ti)/indium tin oxide (ITO), but the embodiments of the present disclosure are not limited thereto.

The plurality of communication lines NL may be arranged in an area between the plurality of pixels PX. The plurality of communication lines NL may be arranged to be extended in a row direction or the first direction X in the area between the plurality of pixels PX. The plurality of communication lines NL may be arranged in an area between a plurality of second electrodes CE2 and may not overlap the plurality of second electrodes CE2. For example, the plurality of communication lines NL may be lines used for short-range communication such as near field communication (NFC). The plurality of communication lines NL may function as antennas. For example, the plurality of communication lines NL may be a plurality of connection lines, etc., but the embodiments of the present disclosure are not limited thereto. In another example, the communication lines NL may be omitted when necessary.

According to the present disclosure, a bank BNK may be arranged in each of the plurality of subpixels. A plurality of banks BNK may be structures in which a plurality of main light emitting diodes MED and redundancy light emitting diodes RED are mounted. The plurality of banks BNK may guide positions of the plurality of main light emitting diodes MED and redundancy light emitting diodes RED in a transfer process in which the plurality of main light emitting diodes MED and the redundancy light emitting diodes RED are transferred. In the transfer process of the plurality of main light emitting diodes MED and redundancy light emitting diodes RED, the plurality of main light emitting diodes MED and redundancy light emitting diodes RED may be transferred on the plurality of banks BNK. The entire area of the main light emitting diode MED and the redundancy light emitting diode RED may overlap the bank BNK. The plurality of banks BNK may be bank patterns or structures, but the embodiments of the present disclosure are not limited thereto.

The bank BNK of the first subpixel SP1, the bank BNK of the second subpixel SP2, and the bank BNK of the third subpixel SP3 may be arranged to be spaced apart from one another. The bank BNK of the first subpixel SP1, the bank BNK of the second subpixel SP2, and the bank BNK of the third subpixel SP3 may be configured to be separated. Accordingly, the banks BNK of the first subpixel SP1, the second subpixel SP2, and the third subpixel SP3, to which different types of main light emitting diodes MED are transferred, may be easily identified.

The bank BNK of the first main subpixel SPla and the bank BNK of the first blank subpixel SP1b may be connected to each other or integrated with each other or may be formed to be spaced apart or separated from each other. In addition, the bank BNK of the second main subpixel SP2a and the bank BNK of the second blank subpixel SP2b may be connected to each other or integrated with each other or may be formed to be spaced apart or separated from each other. The bank BNK of the third main subpixel SP3a and the bank BNK of the third blank subpixel SP3b may be connected to each other or integrated with each other or may be formed to be spaced apart or separated from each other. Accordingly, the bank BNK of the first subpixel SP1, the bank BNK of the second subpixel SP2, and the bank BNK of the third subpixel SP3 may be formed in various ways, and the embodiments of the present disclosure are not limited thereto.

For example, the plurality of banks BNK may be formed of an organic insulating material. The plurality of banks BNK may be formed of a single layer or a multi-layer of an organic insulating material such as acryl resin, epoxy resin, phenolic resin, polyamide resin, and/or polyimide resin, etc. For example, the plurality of banks BNK may be formed of a photo resist, polyimide (PI), or an acryl-based material, but the embodiments of the present disclosure are not limited thereto. Alternatively, the bank BNK may include an inorganic insulating material such as silicon nitride, aluminum nitride, zirconium nitride, titanium nitride, hafnium nitride, tantalum nitride, silicon oxide, aluminum oxide, or titanium oxide, etc. The bank BNK serves to define a subpixel. Thus, the bank BNK may be made of an insulating material containing a black material. The bank BNK may be made of, for example, a transparent carbon-based mixture. Specifically, the bank BNK may contain carbon black, but is not limited thereto. The bank may also be made of a transparent insulating material.

The first electrode CE1 may be arranged in each of the plurality of subpixels. The first electrode CE1 may be arranged on the bank BNK while overlapping the bank BNK. The first electrode CE1 may be electrically connected to one signal line TL among the plurality of signal lines TL. At least a portion of the first electrode CE1 may be extended to the outside of the bank BNK and thus be electrically connected to the signal line TL closest to the first electrode CE1. A portion of the first electrode CE1 may overlap the bank BNK, and the other portion of the first electrode CE1 may not overlap the bank BNK. For example, referring to FIGS. 6A and 6B, a portion of the first electrode CE1 of the first main subpixel SPla may be extended to one side area of the first main subpixel SPla and thus be electrically connected to the second signal line TL2, and a portion of the first electrode CE1 of the first blank subpixel SP1b may be extended to the other side area of the first blank subpixel SP1b and thus be electrically connected to the first signal line TL1. A portion of the first electrode CE1 of the second main subpixel SP2a may be extended to one side area of the second main subpixel SP2a and thus be electrically connected to the third signal line TL3, and a portion of the first electrode CE1 of the second blank subpixel SP2b may be extended to the other side area of the second blank subpixel SP2b and thus be electrically connected to the fourth signal line TL4. A portion of the first electrode CE1 of the third main subpixel SP3a may be extended to one side area of the third main subpixel SP3a and thus be electrically connected to the sixth signal line TL6, and a portion of the first electrode CE1 of the third blank subpixel SP3b may be extended to the other side area of the third blank subpixel SP3b and thus be electrically connected to the fifth signal line TL5.

The first electrode CE1 is electrically connected to the anode electrode (134 of FIG. 9) of the main light emitting diode MED and the redundancy light emitting diode RED. The anode voltage from the pixel driving circuit (PD of FIG. 3) may be sequentially transmitted to the main light emitting diode MED and the redundancy light emitting diode RED via the signal line TL and the first electrode CE1 in this order. A different voltage may be applied to the first electrode CE1 of each of the plurality of subpixels depending on an image displayed thereon. For example, different voltages may be applied to the first electrode CE1 of each of the plurality of subpixels. Accordingly, the first electrode CE1 may be a pixel electrode, and embodiments of the present disclosure are not limited thereto.

The first electrode CE1 may be made of a conductive material. For example, the first electrode CE1 may be formed integrally with the plurality of signal lines TLs. For example, the first electrode CE1 may be made of the same conductive material as that of the plurality of signal lines TLs, but the embodiments of the present disclosure are not limited thereto. For example, the first electrode CE1 may be made of a conductive material such as titanium (Ti), aluminum (Al), copper (Cu), molybdenum (Mo), nickel (Ni), chromium (Cr), indium tin oxide (ITO), indium zinc oxide (IZO), and indium gallium zinc oxide (IGZO), but the embodiments of the present disclosure are not limited thereto. In another example, the first electrode CE1 may be formed of a multi-layered structure of a conductive material. For example, the plurality of first electrodes CE1 may be formed of a multi-layered structure of titanium (Ti)/aluminum (Al)/titanium (Ti)/titanium tin oxide (ITO), but the embodiments of the present disclosure are not limited thereto.

The main light emitting diode MED may be arranged in each of the plurality of subpixels. The plurality of main light emitting diodes MED and redundancy light emitting diodes RED may be any one of a light emitting diode (LED) and a micro light emitting diode (Micro LED), but the embodiments of the present disclosure are not limited thereto. The plurality of main light emitting diodes MED and redundancy light emitting diodes RED may be arranged on the bank BNK and the first electrode CE1 while overlapping the bank BNK and the first electrode CE1. The entire area of the plurality of main light emitting diodes MED may overlap the bank BNK and the first electrode CE1. Also, the entire area of the redundancy light emitting diode RED may overlap the bank BNK and the first electrode CE1.

The plurality of main light emitting diodes MED and redundancy light emitting diodes RED are arranged on the first electrode CE1 and may be electrically connected to the first electrode CE1. Accordingly, the main light emitting diode MED and the redundancy light emitting diode RED may emit light by receiving the anode voltage from the pixel driving circuit PD through the signal line TL and the first electrode CE1.

The plurality of main light emitting diodes MED may include a first main light emitting diode 130, a second main light emitting diode 140, and a third main light emitting diode 150. The first main light emitting diode 130 may be arranged in the first subpixel SP1. The second main light emitting diode 140 may be arranged in the second subpixel SP2. The third main light emitting diode 150 may be arranged in the third subpixel SP3. For example, one of the first main light emitting diode 130, the second main light emitting diode 140, and the third main light emitting diode 150 may be a red light emitting diode, another one may be a green light emitting diode, and the other one may be a blue light emitting diode, but the embodiments of the present disclosure are not limited thereto. Accordingly, light of various colors including white may be implemented by combining red light, green light and blue light, which are emitted from the plurality of main light emitting diodes MED. Types of the plurality of main light emitting diodes MED are exemplary, and the embodiments of the present disclosure are not limited thereto. The redundancy light emitting diode RED may implement light of the same color as that of the main light emitting diode MED in which a defect occurs.

According to an embodiment of the present disclosure, any one of the first main light emitting diodes 130, the second main light emitting diode 140, and the third main light emitting diode 150 of the plurality of main light emitting diodes MED may have a transfer defect. For example, FIG. 6A illustrates a state that a transfer defect occurs in the second main light emitting diode 140.

The second electrode CE2 may be arranged in each of the plurality of subpixels. The second electrode CE2 may be arranged on the main light emitting diode MED and the redundancy light emitting diode RED. The second electrode CE2 may be electrically connected to the pixel driving circuit (PD of FIG. 3) through a plurality of contact electrodes CCE.

For example, the second electrode CE2 may be electrically connected to a cathode electrode (135 of FIG. 9) of the main light emitting diode MED and the redundancy light emitting diode RED to transfer a cathode voltage from the pixel driving circuit (PD of FIG. 3) to the main light emitting diode MED and the redundancy light emitting diode RED. The same cathode voltage may be applied to the second electrode CE2 of each of the plurality of subpixels. For example, the same voltage may be applied to the second electrode CE2 of each of the plurality of subpixels and the cathode electrode (135 of FIG. 9) of the main light emitting diode MED and the redundancy light emitting diode RED. Accordingly, the second electrode CE2 may be a common electrode, but the embodiments of the present disclosure are not limited thereto.

At least some of the plurality of subpixels may share the second electrode CE2. At least some of the second electrodes CE2 of each of the plurality of subpixels may be integrally formed to be electrically connected. As the same voltage is applied to the second electrodes CE2, the second electrodes CE2 of at least some of the subpixels may be shared and used. For example, the second electrodes CE2 of at least some of the pixels PX arranged in the same row in a horizontal direction may be integrally formed and connected to each other. For example, one second electrode CE2 may be arranged in the plurality of pixels PX. One second electrode CE2 may be arranged in every n subpixels.

For example, some of the second electrodes CE2 of each of the plurality of subpixels may be arranged to be spaced apart or separated from each other. For example, the second electrode CE2 connected to the pixels PX of the (n)th row and the second electrode CE2 connected to the pixels PX of the (n+1)th row may be arranged to be spaced apart or separated from each other. For example, the plurality of second electrodes CE2 may be arranged to be spaced apart from each other with the plurality of communication lines NL extended in a row direction and interposed therebetween. Accordingly, the number of the plurality of subpixels may be greater than the number of the plurality of second electrodes CE2. In another example, all of the second electrodes CE2 of the plurality of subpixels may be integrally connected so that only one second electrode CE2 may be arranged on the substrate 110, and embodiments of the present disclosure are not limited thereto.

The plurality of second electrodes CE2 may be formed of a transparent conductive material, but the embodiments of the present disclosure are not limited thereto. The plurality of second electrodes CE2 may be formed of a transparent conductive material such that light emitted from the main light emitting diode MED and the redundancy light emitting diode RED is directed toward an upper portion of the second electrode CE2. For example, the second electrode CE2 may be formed of a transparent conductive material such as indium tin oxide (ITO), indium zinc oxide (IZO), and indium gallium zinc oxide (IGZO), but the embodiments of the present disclosure are not limited thereto.

The plurality of contact electrodes CCE may be arranged on the substrate 110. For example, the plurality of contact electrodes CCE may be arranged to be spaced apart from the plurality of banks BNK and the plurality of signal lines TL. Each of the plurality of second electrodes CE2 may overlap at least one contact electrode CCE. For example, one second electrode CE2 may overlap the plurality of contact electrodes CCE.

For example, the plurality of contact electrodes CCE may be electrically connected to the plurality of second electrodes CE2. The plurality of contact electrodes CCE may be arranged between the substrate 110 and the plurality of second electrodes CE2 to transfer the cathode voltage from the pixel driving circuit (PD of FIG. 3) to the second electrode CE2.

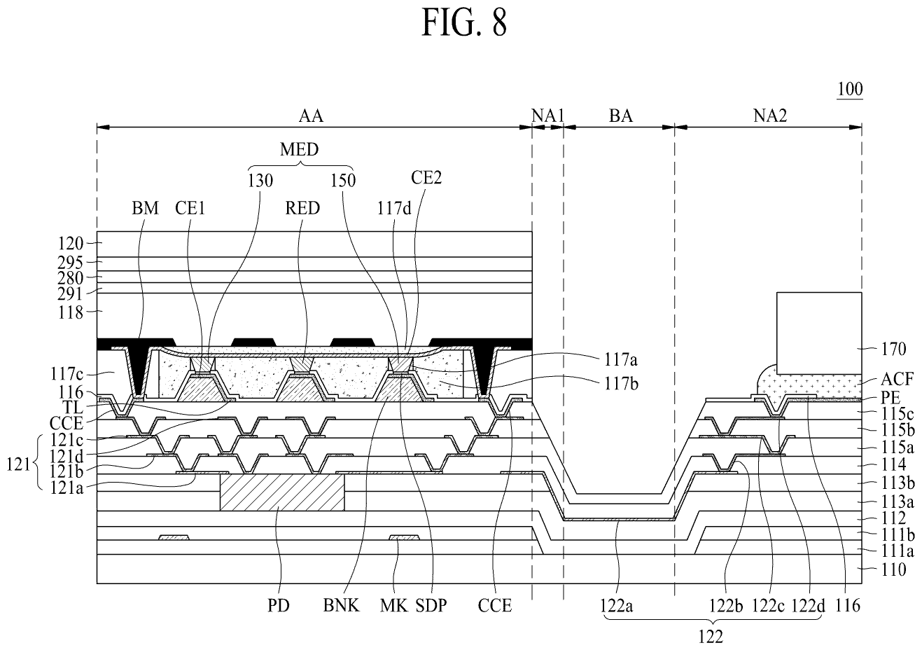

FIG. 8 is a cross-sectional view illustrating a display apparatus according to an embodiment of the present disclosure. FIG. 9 is a cross-sectional view illustrating a display apparatus according to an embodiment of the present disclosure. For example, FIG. 8 is a cross-sectional view of a display area AA, a first non-display area NA, a bending area BA, and a second non-display area NA2, and FIG. 9 is a cross-sectional view of a portion of the display area AA.

Referring to FIG. 8, a first buffer layer 111a and a second buffer layer 111b may be arranged in the remaining area of the substrate 110 except the bending area BA.

The first buffer layer 111a and the second buffer layer 111b may be arranged in the display area AA, the first non-display area NA1, and the second non-display area NA2. The first buffer layer 111a and the second buffer layer 111b may reduce permeation of moisture or impurities through the substrate 110. The first buffer layer 111a and the second buffer layer 111b may be made of an inorganic insulating material. For example, the first buffer layer 111a and the second buffer layer 111b may be formed of a single layer or a multi-layer of silicon oxide (SiOx) or silicon nitride (SiNx), but the embodiments of the present disclosure are not limited thereto.

For example, portions of the first buffer layer 111a and the second buffer layer 111b on the bending area BA may be removed. The upper surface of the substrate 110 positioned in the bending area BA may be exposed without being covered by the first buffer layer 111a and the second buffer layer 111b. By removing the first buffer layer 111a and the second buffer layer 111b, which are made of an inorganic insulating material, from the bending area BA, cracks in the first buffer layer 111a and the second buffer layer 111b, which may occur during bending, may be minimized or reduced.

A plurality of alignment keys MK may be arranged between the first buffer layer 111a and the second buffer layer 111b. A plurality of alignment keys MK may be configured to identify a position of the pixel driving circuit PD during a manufacturing process of the display panel 100. For example, the plurality of alignment keys MK may be configured to align the position of the pixel driving circuit PD transferred onto an adhesive layer 112. In another example, the plurality of alignment keys MK may be omitted.

The adhesive layer 112 may be arranged on the second buffer layer 111b. The adhesive layer 112 may be arranged in the display area AA, the first non-display area NA1, the bending area BA, and the second non-display area NA2. In another example, at least a portion of the adhesive layer 112 may be removed from the non-display areas NA1 and NA2 including the bending area BA. For example, the adhesive layer 112 may be formed of any one of an adhesive polymer, an epoxy resin, a UV curable resin, a polyimide-based resin, an acrylate-based material, a urethane-based material, and a polydimethylsiloxane (PDMS), but the embodiments of the present disclosure are not limited thereto.

In the display area AA, the pixel driving circuit PD may be arranged on the adhesive layer 112. When the pixel driving circuit PD is implemented as a pixel driver, the pixel driver may be packaged on the adhesive layer 112 through a transfer process, but the embodiments of the present disclosure are not limited thereto.

The first protective layer 113a and the second protective layer 113b may be arranged on the adhesive layer 112 and the pixel driving circuit PD. The first protective layer 113a and the second protective layer 113b may be arranged to surround a side of the pixel driving circuit PD, but the embodiments of the present disclosure are not limited thereto. For example, the second protective layer 113b may be arranged to cover at least a portion of the upper surface of the pixel driving circuit PD. For example, at least one of the first protective layer 113a or the second protective layer 113b, which are arranged on the bending area BA, may be omitted. For example, the first protective layer 113a may be entirely arranged in the display area AA and the non-display area NA, and the second protective layer 113b may be partially arranged in the display area AA, the first non-display area NA1 and the second non-display area NA2 and may not be arranged in the bending area BA. For example, a portion of the second protective layer 113b in the bending area BA may be removed. However, the embodiments of the present disclosure are not limited to these examples.

The first protective layer 113a and the second protective layer 113b may be made of an organic insulating material, but the embodiments of the present disclosure are not limited thereto. For example, the first protective layer 113a and the second protective layer 113b may be made of a photo resist, polyimide (PI), a photoacryl-based material, or the like, but the embodiments of the present disclosure are not limited thereto. For example, the first protective layer 113a and the second protective layer 113b may be overcoating layers or insulating layers, but the embodiments of the present disclosure are not limited thereto.

According to the present disclosure, a plurality of first connection lines 121 may be arranged on the second protective layer 113b in the display area AA. The plurality of first connection lines 121 may be lines for electrically connecting the pixel driving circuit PD to other elements. For example, the pixel driving circuit PD may be electrically connected to a plurality of signal lines TL, a plurality of contact electrodes CCE, and the like through the plurality of first connection lines 121. For example, the plurality of first connection lines 121 may include a first main connection line 121a, a (1-2)th connection line 121b, a (1-3)th connection line 121c, and a (1-4)th connection line 121d, but the embodiments of the present disclosure are not limited thereto.

For example, a plurality of first main connection lines 121a may be arranged on the second protective layer 113b. The plurality of first main connection lines 121a may be electrically connected to the pixel driving circuit PD. The plurality of first main connection lines 121a may transfer a voltage output from the pixel driving circuit PD to the first electrode CE1 or the second electrode CE2.

For example, a third protective layer 114 may be arranged on the second protective layer 113b. The third protective layer 114 may be entirely arranged in the display area AA and the non-display area NA. In the bending area BA, the third protective layer 114 may cover a side of the second protective layer 113b and an upper surface of the first protective layer 113a. The third protective layer 114 may be made of an organic insulating material. For example, the third protective layer 114 may be made of a photo resist, polyimide (PI), or a photoacryl-based material, but the embodiments of the present disclosure are not limited thereto. For example, the first protective layer 113a, the second protective layer 113b, and the third protective layer 114 may be made of the same material, but the embodiments of the present disclosure are not limited thereto.

A plurality of (1-2)th connection lines 121b may be arranged on the third protective layer 114. The plurality of (1-2)th connection lines 121b may be connected to the pixel driving circuit PD through the first main connection lines 121a, or may be directly connected to the pixel driving circuit PD. For example, a portion of the (1-2)th connection lines 121b may be directly connected to the pixel driving circuit PD through a contact hole of the third protective layer 114. The other portion of the (1-2)th connection lines 121b may be electrically connected to the first main connection line 121a through the contact hole of the third protective layer 114, but the embodiments of the present disclosure are not limited thereto. For example, a voltage output from the pixel driving circuit PD may be transferred to the first electrode CEL or the second electrode CE2 through connection lines different from the plurality of (1-2)th connection lines 121b.

A first insulating layer 115a may be arranged on the plurality of (1-2)th connection lines 121b. The first insulating layer 115a may be entirely arranged in the display area AA and the non-display area NA, but the embodiments of the present disclosure are not limited thereto. The first insulating layer 115a may be made of an organic insulating material, but the embodiments of the present disclosure are not limited thereto. For example, the first insulating layer 115a may be made of a photo resist, polyimide (PI), or a photoacryl-based material, but the embodiments of the present disclosure are not limited thereto.

A plurality of (1-3)th connection lines 121c may be arranged on the first insulating layer 115a. The plurality of (1-3)th connection lines 121c may be electrically connected to the plurality of (1-2)th connection lines 121b. For example, the (1-3)th connection line 121c may be electrically connected to the (1-2)th connection line 121b through a contact hole of the first insulating layer 115a.

A second insulating layer 115b may be arranged on the plurality of (1-3)th connection lines 121c. The second insulating layer 115b may be arranged in the remaining area except the bending area BA, but the embodiments of the present disclosure are not limited thereto. The second insulating layer 115b may be arranged in the display area AA, the first non-display area NA1, and the second non-display area NA2, but the embodiments of the present disclosure are not limited thereto. For example, at least a portion of the second insulating layer 115b arranged in the bending area BA may be removed. The second insulating layer 115b may be made of an organic insulating material, but the embodiments of the present disclosure are not limited thereto. For example, the second insulating layer 115b may be made of a photo resist, polyimide (PI), or a photoacryl-based material, but the embodiments of the present disclosure are not limited thereto.

A plurality of (1-4)th connection lines 121d may be arranged on the second insulating layer 115b. The plurality of (1-4)th connection lines 121d may be electrically connected to the plurality of (1-3)th connection lines 121c. For example, the (1-4)th connection line 121d may be electrically connected to the (1-3)th connection line 121c through a contact hole of the second insulating layer 115b.

The (1-4)th connection line 121d may be connected to the contact electrode CCE through a contact hole of the third insulating layer 115c, and accordingly, the contact electrode CCE and the pixel driving circuit PD may be electrically connected to each other by the first connection line 121.

Although not shown, the (1-4)th connection line 121d may be directly connected to the signal line TL through the contact hole provided in the third insulating layer 115c or may be electrically connected to the signal line TL through other additional line or electrode, and accordingly, the signal line TL and the pixel driving circuit PD may be electrically connected to each other by the first connection line 121.

According to the present disclosure, a plurality of second connection lines 122 may be arranged on the second protective layer 113b in the non-display area NA. The plurality of second connection lines 122 may be lines for transmitting a signal transferred from a flexible circuit board (or a flexible film) (170 of FIG. 2) and a printed circuit board (160 of FIG. 2) to the pixel driving circuit PD of the display area AA.

For example, the plurality of second connection lines 122 may be electrically connected to a plurality of pad electrodes PE to receive signals from the flexible circuit board (or the flexible film) (170 of FIG. 2) and the printed circuit board (160 of FIG. 2).

For example, the plurality of second connection lines 122 may be extended from a pad portion (PAD of FIG. 2) toward the display area AA to transmit signals to the lines of the display area AA. In this case, the plurality of second connection lines 122 may function as link lines (LL of FIG. 3). The plurality of second connection lines 122 may include a second main connection line 122a, a (2-2)th connection line 122b, a (2-3)th connection line 122c, and a (2-4)th connection line 122d.

A plurality of second main connection lines 122a may be arranged on the second protective layer 113b. The plurality of second main connection lines 122a may be extended from the second non-display area NA2 to the bending area BA and the first non-display area NA1. The plurality of second main connection lines 122a may transmit the signals transmitted from the flexible circuit board (or the flexible film) (170 of FIG. 2) and the printed circuit board (160 of FIG. 2) to the pad portion (PAD of FIG. 2) to the pixel driving circuit PD of the display area AA. Accordingly, the plurality of second main connection lines 122a may be electrically connected to the pad electrode PE and the pixel driving circuit PD, respectively. For example, although not shown, the (2-1)th connection lines 122a may be extended to the display area AA and thus directly connected to the pixel driving circuit PD in the display area AA or may be electrically connected to the pixel driving circuit PD through other additional lines or electrodes. In addition, the (2-1)th connection line 122a may be electrically connected to the pad electrode PE in the second non-display area NA2 via the (2-2)th connection line 122b, the (2-3)th connection line 122c, and the 2-4 connection line 122d. Therefore, the pixel driving circuit PD and the pad electrode PE may be electrically connected to each other by the second connection line 122.

A plurality of (2-2)th connection lines 122b may be arranged on the third protective layer 114. The plurality of (2-2)th connection lines 122b may be arranged in the second non-display area NA2. The (2-2)th connection line 122b may be electrically connected to the second main connection line 122a through a contact hole of the third protective layer 114. Therefore, the signals from the flexible circuit board (or the flexible film) (170 of FIG. 2) and the printed circuit board (160 of FIG. 2) may be transmitted to the second main connection line 122a through the (2-2)th connection line 122b.

The (2-3)th connection line 122c may be arranged on the first insulating layer 115a. The (2-3)th connection line 122c may be arranged in the second non-display area NA2. The (2-3)th connection line 122c may be electrically connected to the (2-2)th connection line 122b through the contact hole of the first insulating layer 115a. Therefore, the signals from the flexible circuit board (or the flexible film) (170 of FIG. 2) and the printed circuit board (160 of FIG. 2) may be transmitted to the second main connection line 122a through the (2-3)th connection line 122c and the (2-2)th connection line 122b.

The (2-4)th connection line 122d may be arranged on the second insulating layer 115b. The (2-4)th connection line 122d may be arranged in the second non-display area NA2. The (2-4)th connection line 122d may be electrically connected to the (2-3)th connection line 122c through the contact hole of the second organic insulating layer 115b. Therefore, the signals from the flexible circuit board (or the flexible film) (170 of FIG. 2) and the printed circuit board (160 of FIG. 2) may be transmitted to the second main connection line 122a through the (2-4)th connection line 122d, the (2-3)th connection line 122c, and the (2-2)th connection line 122b.

The plurality of first connection lines 121 and the plurality of second connection lines 122 may be formed of a conductive material having excellent flexibility or one of various conductive materials used in the display area AA. For example, the second connection line 122 partially arranged in the bending area BA may be made of a conductive material having excellent flexibility, such as gold (Au), silver (Ag), or aluminum (Al), but the embodiments of the present disclosure are not limited thereto. In another example, the plurality of first connection lines 121 and the plurality of second connection lines 122 may be formed of molybdenum (Mo), chromium (Cr), titanium (Ti), nickel (Ni), neodymium (Nd), copper (Cu), an alloy of silver (Ag) and magnesium (Mg), or their alloy, but the embodiments of the present disclosure are not limited thereto.

The third insulating layer 115c may be arranged on the plurality of first connection lines 121 and the plurality of second connection lines 122. The third insulating layer 115c may be arranged in the remaining area except the bending area BA, but the embodiments of the present disclosure are not limited thereto. The third insulating layer 115c may be arranged in the display area AA, the first non-display area NA1, and the second non-display area NA2. At least a portion of the third insulating layer 115c in the bending area BA may be removed. The third insulating layer 115c may be made of an organic insulating material, but the embodiments of the present disclosure are not limited thereto. For example, the third insulating layer 115c may be made of a photo resist, polyimide (PI), or a photo acryl-based material, but the embodiments of the present disclosure are not limited thereto.

A plurality of banks BNK may be arranged on the third insulating layer 115c in the display area AA. The plurality of banks BNK may be arranged to overlap each of a plurality of subpixels. The plurality of banks BNK may not be arranged in the first non-display area NA1, the second non-display area NA2, and the bending area BA.

A plurality of signal lines TL may be arranged on the third insulating layer 115c in the display area AA. The plurality of signal lines TL may be arranged in an area between the plurality of banks BNK. For example, the plurality of signal lines TL may be arranged adjacent to any one of the plurality of banks BNK. Each of the plurality of signal lines TL may be electrically connected to the first connection line 121, for example, the (1-4)th connection line 121d.

The plurality of contact electrodes CCE may be arranged on the third insulating layer 115c in the display area AA. The plurality of contact electrodes CCE may supply a cathode voltage from the pixel driving circuit PD to the second electrode CE2. Each of the plurality of contact electrodes CCE may be electrically connected to the first connection line 121, for example, the (1-4)th connection line 121d.

A first electrode CE1 may be arranged on the bank BNK. For example, the first electrode CE1 may be arranged to be extended from the adjacent signal line TL toward an upper portion of the bank BNK. The first electrode CE1 may be arranged on an upper surface of the bank BNK and a side of the bank BNK. For example, the first electrode CE1 may be arranged to be extended from the signal line TL on the upper surface of the third insulating layer 115c to the side of the bank BNK and the upper surface of the bank BNK. The first electrode CE1 may be integrally formed with the signal line TL.

Referring to FIG. 9, the first electrode CE1 may include a plurality of conductive layers. For example, the first electrode CE1 may include a first conductive layer CE1a, a second conductive layer CE1b, a third conductive layer CE1c, and a fourth conductive layer CE1d, but the embodiments of the present disclosure are not limited thereto.

The first conductive layer CE1a may be arranged on the bank BNK. The second conductive layer CE1b may be arranged on the first conductive layer CE1a. The third conductive layer CE1c may be arranged on the second conductive layer CE1b, and the fourth conductive layer CE1d may be arranged on the third conductive layer CE1c. For example, each of the first conductive layer CE1a, the second conductive layer CE1b, the third conductive layer CE1c, and the fourth conductive layer CE1d may be made of titanium (Ti), molybdenum (Mo), aluminum (Al), or titanium (Ti) and indium tin oxide (ITO), but the embodiments of the present disclosure are not limited thereto.

According to the present disclosure, some conductive layers having good reflection efficiency among the plurality of conductive layers constituting the first electrode CE1 may include an alignment key for aligning the main light emitting diode MED and the redundancy light emitting diode RED and/or a reflective plate. For example, among the plurality of conductive layers of the first electrode CE1, the second conductive layer CE1b may include a reflective material. For example, the second conductive layer CE1b may include aluminum (Al), but the embodiments of the present disclosure are not limited thereto. Thus, the second conductive layer CE1b may be formed of a reflective plate. Also, due to high reflection efficiency of the second conductive layer CE1b, identification may be easily performed in a manufacturing process, and thus the positions or transfer positions of the main light emitting diode MED and the redundancy light emitting diode RED may be aligned based on the second conductive layer CE1b.

For example, in order to form the second conductive layer CE1b as a reflective plate, the third conductive layer CE1c and the fourth conductive layer CE1d, which cover the second conductive layer CE1b, may be partially removed or etched. For example, portions of the third and fourth conductive layers CE1c and CE1d arranged on the bank BNK may be removed or etched to expose an upper surface of the second conductive layer CE1b. For example, a central portion and an edge portion (or corner portion) of the third and fourth conductive layers CE1c and CE1d, on which a solder pattern SDP is arranged, may remain, and the other portions other than the central portion and the edge portion may be removed. For example, the edge portion (or the corner portion) and the central portion of each of the third conductive layer CE1c made of titanium (Ti) and the fourth conductive layer CE1d made of indium tin oxide (ITO) may not be etched. Thus, another conductive layer of the first electrode CE1 may be prevented or obviated from being corroded by a tetramethylammonium hydroxide (TMAH) solution used in a mask process of the first electrode CE1.

According to the present disclosure, the first conductive layer CE1a and the third conductive layer CE1c may include titanium (Ti) or molybdenum (Mo). The second conductive layer CE1b may include aluminum (Al). The fourth conductive layer CE1d may include a transparent conductive oxide layer such as indium tin oxide (ITO) or indium zinc oxide (IZO) having good adhesion to the solder pattern SDP and corrosion resistance and acid resistance, but the embodiments of the present disclosure are not limited thereto.

The first conductive layer CE1a, the second conductive layer CE1b, the third conductive layer CE1c, and the fourth conductive layer CE1d may be sequentially deposited and then patterned by a photolithography process and an etching process, but the embodiments of the present disclosure are not limited thereto.

As shown in FIGS. 8 and 9, according to the present disclosure, the signal line TL, the contact electrode CCE, and the pad electrode PE, which are arranged on the same layer as the first electrode CE1, may be formed of multiple layers of a conductive material, but the embodiments of the present disclosure are not limited thereto. For example, the signal line TL, the contact electrode CCE, and the pad electrode PE may be formed of multiple layers of indium tin oxide (ITO)/titanium (Al)/titanium (Ti), but the embodiments of the present disclosure are not limited thereto.

According to the present disclosure, the solder pattern SDP may be arranged on the first electrode CE1 in each of the plurality of subpixels. The solder pattern SDP may bond the main light emitting diode MED and the redundancy light emitting diode RED to the first electrode CE1. The first electrode CE1, the light emitting diode MED, and the redundancy light emitting diode RED may be electrically connected to one another through eutectic bonding using the solder pattern SDP, but the embodiments of the present disclosure are not limited thereto. For example, when the solder pattern SDP is made of indium (In), and the anode electrode 134 of the main light emitting diode MED and the redundancy light emitting diode RED is made of gold (Au), the solder pattern SDP and the anode electrode 134 may be bonded to each other by applying heat and pressure to the main light emitting diode MED and the redundancy light emitting diode RED during a transfer process. The main light emitting diode MED and the redundancy light emitting diode RED may be bonded to the solder pattern SDP and the first electrode CE1 without a separate adhesive through eutectic bonding. For example, the solder pattern SDP may be made of indium (In), tin (Sn), or their alloy, but the embodiments of the present disclosure are not limited thereto. For example, the solder pattern SDP may be a bonding pad, but the embodiments of the present disclosure are not limited thereto.

According to the present disclosure, a passivation layer 116 may be arranged on the plurality of signal lines TL, the plurality of first electrodes CE1, the plurality of contact electrodes CCE, and the third insulation layer 115c. For example, the passivation layer 116 may be arranged in the display area AA, the first non-display area NA1, and the second non-display area NA2. At least a portion of the passivation layer 116 arranged in the bending area BA may be removed. A portion of the passivation layer 116 covering the plurality of pad electrodes PE may be removed from the second non-display area NA2. A portion of the passivation layer 116 covering the plurality of contact electrodes CCE may be removed from the display area AA. The passivation layer 116 covering the solder pattern SDP may be removed from the display area AA. The passivation layer 116 may cover the first electrode CE1. The passivation layer 116 may cover a portion of the exposed upper surface of the second conductive layer CE1b.

Since the passivation layer 116 is arranged to expose at least a portion of the plurality of pad electrodes PE, the plurality of contact electrodes CCE and the solder pattern SDP, and cover the other areas, permeation of moisture or impurities flowing into the main light emitting diode MED and the redundancy light emitting diode RED may be reduced. For example, the passivation layer 116 may be composed of a single layer or multiple layers of silicon oxide (SiOx) or silicon nitride (SiNx), but the embodiments of the present disclosure are not limited thereto. For example, the passivation layer 116 may be a protective layer or an insulating layer, but the embodiments of the present disclosure are not limited thereto. For example, the passivation layer 116 may include a hole exposing the solder pattern SDP and a hole exposing the contact electrode CCE.

In each of the plurality of subpixels, the main light emitting diode MED and the redundancy light emitting diode RED may be arranged on the solder pattern SDP. A first main light emitting diode 130 may be arranged in the first subpixel SP1. A second main light emitting diode 140 may be arranged in the second subpixel SP2. A third main light emitting diode 150 may be arranged in the third subpixel SP3. In detail, at least one of the first subpixel SP1, the second subpixel SP2 or the third subpixel SP3 may include a redundancy light emitting diode RED. FIGS. 6A and 6B illustrate a state that the second subpixel SP2 includes the redundancy light emitting diode RED.

According to an embodiment of the present disclosure, a transfer defect may occur in any one of the first main light emitting diode 130, the second main light emitting diode 140, and the third main light emitting diode 150 of the plurality of main light emitting diodes MED. For example, FIG. 6A illustrates a state that a transfer defect occurs in the second main light emitting diode 140.

The main light emitting diode MED and redundancy light emitting diode RED can be formed on a silicon wafer by methods such as metal organic chemical vapor deposition (MOCVD), chemical vapor deposition (CVD), plasma-enhanced chemical vapor deposition (PECVD), molecular beam growth (MBE), hydride vapor phase epitaxy (HVPE), or sputtering, but the embodiments of the present disclosure are not limited thereto.

Referring to FIG. 9, the first main light emitting diode 130 may include an anode electrode 134, a first semiconductor layer 131, an active layer 132, a second semiconductor layer 133, a cathode electrode 135, and an encapsulation layer 136, but the embodiments of the present disclosure are not limited thereto. For example, the encapsulation layer 136 may not be included in the first main light emitting diode 130.

The first semiconductor layer 131 may be arranged on the solder pattern SDP. The second semiconductor layer 133 may be arranged on the first semiconductor layer 131.

For example, one of the first semiconductor layer 131 and the second semiconductor layer 133 may be implemented using a compound semiconductor such as a group III-V or a group II-VI and may be doped with impurities (or dopants). For example, one of the first semiconductor layer 131 and the second semiconductor layer 133 may be a semiconductor layer doped with n-type impurities, and the other one may be a semiconductor layer doped with p-type impurities, but the embodiments of the present disclosure are not limited thereto. For example, one or more of the first semiconductor layer 131 and the second semiconductor layer 133 may be a layer doped with n-type or p-type impurities on a material such as gallium nitride (GaN), gallium phosphide (GaP), gallium arsenide phosphide (GaAsP), aluminum gallium indium phosphide (AlGaInP), indium aluminum phosphide (InAlP), aluminum gallium nitride (AlGaN), aluminum indium nitride (AlInN), aluminum indium gallium nitride (AlInGaN), aluminum gallium arsenide (AlGaAs), or gallium arsenide (GaAs), but the embodiments of the present disclosure are not limited thereto. For example, the n-type impurity may be silicon (Si), germanium (Ge), selenium (Se), carbon (C), tellurium (Te), tin (Sn), or the like, but the embodiments of the present disclosure are not limited thereto. For example, the p-type impurity may be magnesium (Mg), zinc (Zn), calcium (Ca), strontium (Sr), barium (Ba), beryllium (Be), or the like, but the embodiments of the present disclosure are not limited thereto.

For example, each of the first semiconductor layer 131 and the second semiconductor layer 133 may be a nitride semiconductor including an n-type impurity and a nitride semiconductor including a p-type impurity, but the embodiments of the present disclosure are not limited thereto. For example, the first semiconductor layer 131 may be a nitride semiconductor including a p-type impurity, and the second semiconductor layer 133 may be a nitride semiconductor including an n-type impurity, but the embodiments of the present disclosure are not limited thereto.

The active layer 132 may be arranged between the first semiconductor layer 131 and the second semiconductor layer 133. The active layer 132 may emit light by receiving holes and electrons from the first semiconductor layer 131 and the second semiconductor layer 133. For example, the active layer 132 may be formed of one of a single well structure, a multi-well structure, a single quantum well structure, a multi-quantum well (MQW) structure, a quantum dot structure, and a quantum line structure, but the embodiments of the present disclosure are not limited thereto. For example, the active layer 132 may be formed of indium gallium nitride (InGaN) or gallium nitride (GaN), but the embodiments of the present disclosure are not limited thereto.

In another example, the active layer 132 may include a multi-quantum well (MQW) structure having a well layer and a barrier layer having a band gap higher than that of the well layer. For example, the active layer 132 may include InGaN as a well layer and may include an AlGaN layer as a barrier layer, but the embodiments of the present disclosure are not limited thereto.

The anode electrode 134 may be arranged between the first semiconductor layer 131 and the solder pattern SDP. For example, the anode electrode 134 may electrically connect the first semiconductor layer 131 to the first electrode CE1. The anode voltage output from the pixel driving circuit PD may be applied to the first semiconductor layer 131 through the signal line TL, the first electrode CE1, and the anode electrode 134. For example, the anode electrode 134 may be formed of a conductive material capable of enabling eutectic bonding with the solder pattern SDP, but the embodiments of the present disclosure are not limited thereto. For example, the anode electrode 134 may be formed of gold (Au), tin (Sn), tungsten (W), silicon (Si), silicon (Ag), titanium (Ti), iridium (Ir), chromium (In), zinc (Zn), lead (Pb), nickel (Ni), platinum (Pt), copper (Cu), or their alloy, but the embodiments of the present disclosure are not limited thereto.

The cathode electrode 135 may be arranged on the second semiconductor layer 133. For example, the cathode electrode 135 may electrically connect the second semiconductor layer 133 to the second electrode CE2. The cathode voltage output from the pixel driving circuit PD may be applied to the second semiconductor layer 133 through the contact electrode CCE, the second electrode CE2, and the cathode electrode 135. The cathode electrode 135 may be formed of a transparent conductive material so that light emitted from the main light emitting diode MED and the redundancy light emitting diode RED may be directed toward an upper portion of the main light emitting diode MED and the redundancy light emitting diode RED, but the embodiments of the present disclosure are not limited thereto. For example, the cathode electrode 135 may be formed of a material such as indium tin oxide (ITO), indium zinc oxide (IZO), and indium gallium zinc oxide (IGZO), but the embodiments of the present disclosure are not limited thereto.

The encapsulation layer 136 may be arranged on at least a portion of the first semiconductor layer 131, the active layer 132, the second semiconductor layer 133, the anode electrode 134, and the cathode electrode 135. For example, the encapsulation layer 136 may surround at least a portion of the first semiconductor layer 131, the active layer 132, the second semiconductor layer 133, the anode electrode 134, and the cathode electrode 135.

For example, the encapsulation layer 136 may protect the first semiconductor layer 131, the active layer 132, and the second semiconductor layer 133. For example, the encapsulation layer 136 may be arranged on a side of the first semiconductor layer 131, a side of the active layer 132, and a side of the second semiconductor layer 133.

For example, the encapsulation layer 136 may be arranged on at least a portion of the anode electrode 134 and the cathode electrode 135, for example, on the edge portion (or corner portion or one side) of the anode electrode 134 and the edge portion (or corner portion or one side) of the cathode electrode 135. At least a portion of the anode electrode 134 may be exposed without being covered by the encapsulation layer 136 to connect the anode electrode 134 to the solder pattern SDP. For example, at least a portion of the cathode electrode 135 may be exposed without being covered by the encapsulation layer 136, thereby connecting the cathode electrode 135 to the second electrode CE2. For example, the encapsulation layer 136 may be formed of an insulating material such as silicon nitride (SiNx) or silicon oxide (SiOx), but the embodiments of the present disclosure are not limited thereto.

In another example, the encapsulation layer 136 may have a structure in which a reflective material is dispersed in a resin layer, but the embodiments of the present disclosure are not limited thereto. For example, the encapsulation layer 136 may be manufactured as a reflector having various structures, but the embodiments of the present disclosure are not limited thereto. Light emitted from the active layer 132 may be reflected upward by the encapsulation layer 136 so that light extraction efficiency may be improved. For example, the encapsulation layer 136 may be a reflective layer, but the embodiments of the present disclosure are not limited thereto.

According to the present disclosure, the main light emitting diode MED and the redundancy light emitting diode RED have been described as vertical structures, but the embodiments of the present disclosure are not limited thereto. For example, the main light emitting diode MED and the redundancy light emitting diode RED may have a lateral structure or a flip chip structure.

Although the first main light emitting diode 130 has been described with reference to FIG. 9, the second main light emitting diode 140 and the third main light emitting diode 150 may have substantially the same structure as the first main light emitting diode 130. For example, the second main light emitting diode 140 and the third main light emitting diode 150 may have substantially the same configuration as the first semiconductor layer 131, the active layer 132, the second semiconductor layer 133, the anode electrode 134, the cathode electrode 135, and the encapsulation layer 136 of the first main light emitting diode 130.

As can be seen from FIGS. 8 and 9, according to the present disclosure, a first optical layer 117a surrounding a plurality of main light emitting diodes MED may be arranged in the display area AA. For example, the first optical layer 117a may be arranged to cover a side S1 of the plurality of main light emitting diodes MED in an area of the plurality of subpixels. For example, the first optical layer 117a may cover a portion of the passivation layer 116. For example, the first optical layer 117a may be arranged between the passivation layer 116 and the second electrode CE2 to surround the side S1 of the main light emitting diode MED. For example, the first optical layer 117a may be a diffusion layer or a sidewall diffusion layer, but the embodiments of the present disclosure are not limited thereto. For example, the first optical layer 117a may be arranged between the passivation layer 116 and the main light emitting diode MED.

According to an embodiment of the present disclosure, the entire area of the first optical layer 117a may overlap the main light emitting diode MED when viewed in a plan view. In detail, referring to FIG. 9, the first optical layer 117a is arranged at an end of the upper surface of the main light emitting diode MED. In more detail, the first optical layer 117a is formed by dry etching using the main light emitting diode MED as a mask.

According to an embodiment of the present disclosure, the first optical layer 117a is arranged on each side of the plurality of main light emitting diodes MED arranged in each of the plurality of pixels PX.

According to an embodiment of the present disclosure, as the first optical layer 117a is arranged, the main light emitting diode MED may be fixed without shaking.

The first optical layer 117a may be formed of an organic insulating material, but the embodiments of the present disclosure are not limited thereto. For example, the first optical layer 117a may be formed of siloxane, and may not include fine particles. In detail, the first optical layer 117a may not include fine metal particles such as titanium dioxide (TiO2) particles.

According to an embodiment of the present disclosure, a second optical layer 117b may be arranged on one surface 117al of the first optical layer 117a. In this case, the one surface 117al of the first optical layer 117a means a direction opposite to a direction directed toward the adjacent main light emitting diode MED.

According to an embodiment of the present disclosure, the first optical layer 117a is arranged between the second optical layer 117b and the main light emitting diode MED. In more detail, the first optical layer 117a is arranged between the second optical layer 117b and the main light emitting diode MED which is in contact with the first optical layer 117a.

The second optical layer 117b may include an organic insulating material in which fine particles are dispersed, but the embodiments of the present disclosure are not limited thereto. For example, the second optical layer 117b may be formed of siloxane in which fine metal particles such as titanium dioxide (TiO2) particles are dispersed, but the embodiments of the present disclosure are not limited thereto. Light from the plurality of main light emitting diodes MED may be scattered by the fine particles dispersed in the second optical layer 117b and emitted to the outside of the display panel 100. Accordingly, the second optical layer 117b may improve extraction efficiency of light emitted from the plurality of main light emitting diodes MED.

According to an embodiment of the present disclosure, the first optical layer 117a and the second optical layer 117b are formed of different materials from each other. In detail, the first optical layer 117a and the second optical layer 117b are formed of different materials from each other through different processes from each other.

The second optical layer 117b may be arranged in each of the plurality of pixels PX or may be arranged together in some pixels PX arranged in the same row, but the embodiments of the present disclosure are not limited thereto. For example, the second optical layer 117b may be arranged in each of the plurality of pixels PX, or the plurality of pixels PX may share one second optical layer 117b. In another example, each of the plurality of subpixels may separately include a second optical layer 117b, but the embodiments of the present disclosure are not limited thereto.

According to the present disclosure, a third optical layer 117c may be arranged on the passivation layer 116 in the display area AA. For example, the third optical layer 117c may be arranged to surround the second optical layer 117b. For example, the third optical layer 117c may be in contact with the side of the second optical layer 117b. For example, the third optical layer 117c may be arranged in the area between the plurality of pixels PX, but the embodiments of the present disclosure are not limited thereto. For example, the third optical layer 117c may be a diffusion layer, a diffusion layer window, or a window diffusion layer, but the embodiments of the present disclosure are not limited thereto.

The third optical layer 117c may be formed of an organic insulating material, but the embodiments of the present disclosure are not limited thereto. The third optical layer 117c may be formed of the same material as that of the first optical layer 117a, but the embodiments of the present disclosure are not limited thereto.

For example, a thickness of the second optical layer 117b may be less than that of the third optical layer 117c, but the embodiments of the present disclosure are not limited thereto. Accordingly, when viewed in a plan view, the area in which the second optical layer 117b is arranged may include a concave portion recessed more inward than an upper surface of the third optical layer 117c.

According to the present disclosure, the second electrode CE2 may be arranged on the first optical layer 117a, the second optical layer 117b, and the third optical layer 117c. For example, the second electrode CE2 may be electrically connected to the plurality of contact electrodes CCE through a contact hole of the third optical layer 117c. For example, the second electrode CE2 may be arranged on the plurality of main light emitting diodes MED and redundancy light emitting diodes RED. For example, the second electrode CE2 may include a transparent conductive oxide such as indium tin oxide (ITO) or indium zinc oxide (IZO), but the embodiments of the present disclosure are not limited thereto. For example, the second electrode CE2 may be arranged to be in contact with the cathode electrode 135. For example, the second electrode CE2 may overlap the entire second optical layer 117b and may overlap a portion of the third optical layer 117c.

The second electrode CE2 may be extended continuously in the first direction X of the substrate 110. Accordingly, the second electrode CE2 may be connected in common to the plurality of pixels PX arranged in the first direction X of the substrate 110. For example, the second electrode CE2 may be connected in common to the plurality of pixels PX.

According to the present disclosure, the second electrode CE2 may be continuously extended onto the first optical layer 117a, the second optical layer 117b, the third optical layer 117c, the main light emitting diode MED, and the redundancy light emitting diode RED. The area in which the second optical layer 117b is arranged may include a concave portion recessed more inwardly than the upper surface of the third optical layer 117c. Accordingly, since a first portion of the second electrode CE2 arranged on the second optical layer 117b is arranged along the concave portion, the first portion may be arranged at a lower position than a second portion of the second electrode CE2 arranged on the third optical layer 117c.

A fourth optical layer 117d may be arranged on the second electrode CE2. The fourth optical layer 117d may be arranged to overlap the plurality of main light emitting diodes MED, the first optical layer 117a, and the second optical layer 117b. For example, the fourth optical layer 117d may be arranged not to overlap the third optical layer 117c. Since the fourth optical layer 117d is arranged on the second electrode CE2 and the plurality of main light emitting diodes MED, a Mura that may occur in some of the plurality of main light emitting diodes MED may be reduced. For example, when the plurality of main light emitting diodes MED are transferred onto the substrate 110 of the display panel 100, an area in which a gap between the plurality of main light emitting diodes MED is not uniform due to a process variation or the like may occur. When the gap between the plurality of main light emitting diodes MED is non-uniform, a light emitting area of each of the plurality of main light emitting diodes MED may be non-uniformly arranged, and thus stain (Mura) may be visually recognized by a user. Accordingly, since the fourth optical layer 117d is configured above the plurality of main light emitting diodes MED to uniformly diffuse light, light emitted from some main light emitting diodes MED may be reduced from being visually recognized like a stain. As a result, since light emitted from the plurality of main light emitting diodes MED is evenly diffused by the fourth optical layer 117d and extracted to the outside of the display panel 100, luminance uniformity of the display apparatus may be improved.

The fourth optical layer 117d may be formed of an organic insulating material in which fine particles are dispersed, but the embodiments of the present disclosure are not limited thereto. For example, the fourth optical layer 117d may be formed of siloxane in which fine metal particles such as titanium dioxide (TiO2) particles are dispersed, but the embodiments of the present disclosure are not limited thereto. For example, the fourth optical layer 117d may be formed of the same material as that of the first optical layer 117a, but the embodiments of the present disclosure are not limited thereto. For example, the fourth optical layer 117d may be a diffusion layer or an upper diffusion layer, but the embodiments of the present disclosure are not limited thereto.

According to the present disclosure, light from the plurality of main light emitting diodes MED may be scattered by the fine particles dispersed in the fourth optical layer 117d and emitted to the outside of the display panel 100. The fourth optical layer 117d may evenly mix the light emitted from the plurality of main light emitting diodes MED, thereby further improving luminance uniformity of the display apparatus. In addition, light extraction efficiency of the display apparatus may be improved by the light scattered from the plurality of fine particles, and thus the display apparatus may be driven at a low power.

In the display area AA, a black matrix BM may be arranged on the second electrode CE2, the first optical layer 117a, the second optical layer 117b, the third optical layer 117c, and the fourth optical layer 117d. For example, the black matrix BM may fill the contact hole of the third optical layer 117c. Since the black matrix BM is configured to cover the display area AA, color mixture and reflection of external light of the plurality of subpixels may be reduced. For example, since the black matrix BM is arranged within a contact hole in which the second electrode CE2 is connected with the contact electrode CCE, light leakage between the plurality of neighboring subpixels may be prevented or reduced.

For example, the black matrix BM may be formed of an opaque material, but the embodiments of the present disclosure are not limited thereto. For example, the black matrix BM may be an organic insulating material to which a black pigment or a black dye is added, but the embodiments of the present disclosure are not limited thereto.

According to an embodiment of the present disclosure, the first optical layer 117a does not overlap the black matrix BM.

Referring to FIG. 8, a cover layer 118 may be arranged on the black matrix BM in the display area AA. The cover layer 118 may protect an element under the cover layer 118. For example, the cover layer 118 may be formed of an organic insulating material, but the embodiments of the present disclosure are not limited thereto. For example, the cover layer 118 may be formed of a photo resist, polyimide (PI), or a photo acryl-based material, but the embodiments of the present disclosure are not limited thereto. For example, the cover layer 118 may be an overcoating layer or an insulating layer, but the embodiments of the present disclosure are not limited thereto.

A polarizing layer 280 may be arranged on the cover layer 118 via a first adhesive layer 291. A cover member 120 may be arranged on the polarizing layer 280 via a second adhesive layer 295. For example, the first adhesive layer 291 and the second adhesive layer 295 may include an optically clear adhesive (OCA), an optically clear resin (OCR), or a pressure sensitive adhesive (PSA), but the embodiments of the present disclosure are not limited thereto.

According to the present disclosure, a plurality of pad electrodes PE may be arranged on the third insulating layer 115c in the second non-display area NA2. For example, at least portions of the plurality of pad electrodes PE may be exposed without being covered by the passivation layer 116. For example, the plurality of pad electrodes PE may be electrically connected to the (2-4)th connection line 122d through the contact hole of the third insulating layer 115c.

An adhesive film ACF may be arranged on the plurality of pad electrodes PE. The adhesive film ACF may be an adhesive layer in which conductive balls are dispersed in an insulating material, but the embodiments of the present disclosure are not limited thereto. When heat or pressure is applied to the adhesive film ACF, the conductive balls may be electrically connected to a portion where heat or pressure is applied, thereby having conductive characteristics. The adhesive film ACF may be arranged between the plurality of pad electrodes PE and the flexible circuit board (or the flexible film) 170, so that the flexible circuit board (or the flexible film) 170 may be attached or bonded to the plurality of pad electrodes PE. For example, the adhesive film ACF may be an anisotropic conductive film (ACF), but the embodiments of the present disclosure are not limited thereto.

The flexible circuit board (or the flexible film) 170 may be arranged on the adhesive film ACF. The flexible circuit board (or the flexible film) 170 may be electrically connected to the plurality of pad electrodes PE through the adhesive film ACF. Therefore, signals output from the flexible circuit board (or the flexible film) 170 and the printed circuit board may be transmitted to the pixel driving circuit PD of the display area AA through the plurality of pad electrodes PE, the (2-4)th connection line 122d, the (2-3)th connection line 122c, the (2-2)th connection line 122b, and the second main connection line 122a.

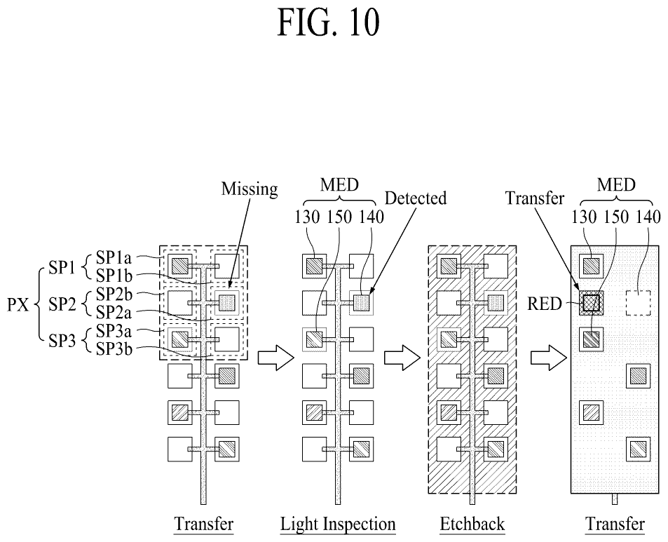

FIG. 10 is a process plan view illustrating a repair process of a light emitting diode according to an embodiment of the present disclosure.

Referring to FIG. 10, the repair process of the light emitting diode according to an embodiment of the present disclosure includes a transfer step, a light inspection step, and a repair step. Hereinafter, the transfer step will be referred to as a ‘first transfer step’.

In detail, the repair step includes an etchback step and a transfer step. The transfer step in the repair step will be referred to as a ‘second transfer step’.

Referring to FIG. 10, in the first transfer step, each of the first main subpixel SPla of the first subpixel SP1, the second main subpixel SP2a of the second subpixel SP2, and the third main subpixel SP3a of the third subpixel SP3 include a main light emitting diode MED, and thus may emit light of red, green, and blue. However, a non-transfer defect occurs in which the second main light emitting diode 140 of the second main subpixel SP2a of the second subpixel SP2 is not transferred. Although FIG. 10 illustrates a non-transfer defect in which the second main light emitting diode 140 is not transferred as an example, the transferred main light emitting diode itself may be a defect despite that the transfer process has been normally performed.

FIG. 10 shows that a transfer defect has occurred in the second main subpixel SP2a, but an embodiment of the present disclosure is not limited thereto, and the transfer defect may occur in the first main subpixel SPla and the third main subpixel SP3a.

Referring to FIG. 10, in the light inspection step, the second main light emitting diode 140 of the second main subpixel SP2a, which has been determined to be defective, may be found through the light inspection.

Referring to FIG. 10, in the etchback step of the repair step, the second electrode CE2 arranged in the pixel PX may be removed through wet etching, and the first optical layer 117a may be removed through dry etching.

Referring to FIG. 10, in the second transfer step of the repair step, the redundancy light emitting diode RED is additionally transferred to the second blank subpixel SP2b arranged adjacent to the same column of the second main subpixel SP2a in which the defect has occurred. In this case, the additionally transferred redundancy light emitting diode RED may emit green light instead of the second main light emitting diode 140.

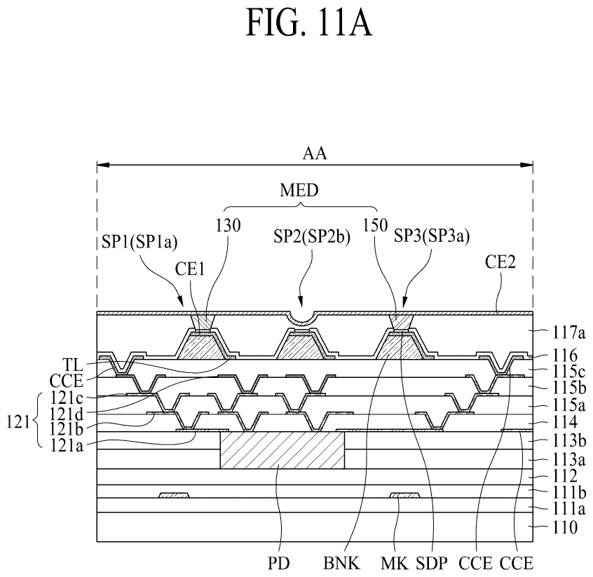

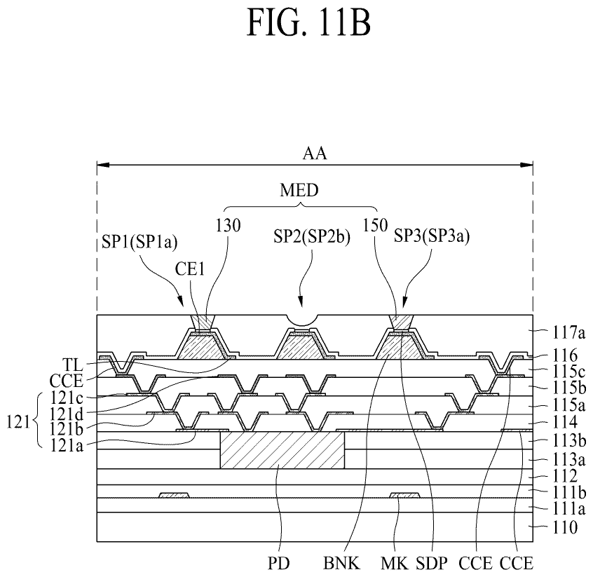

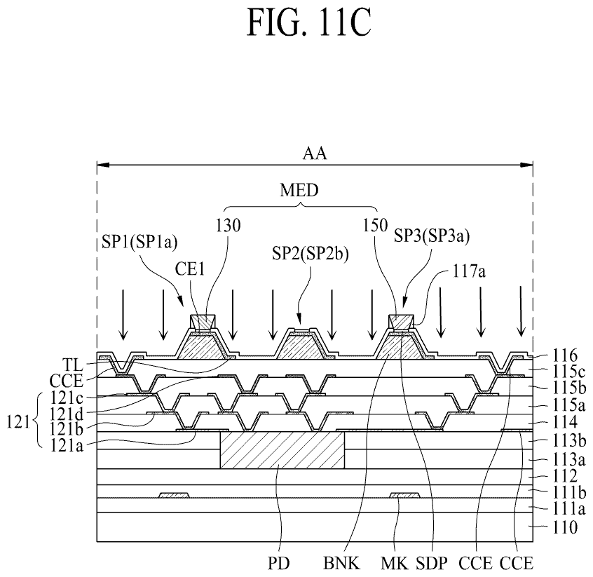

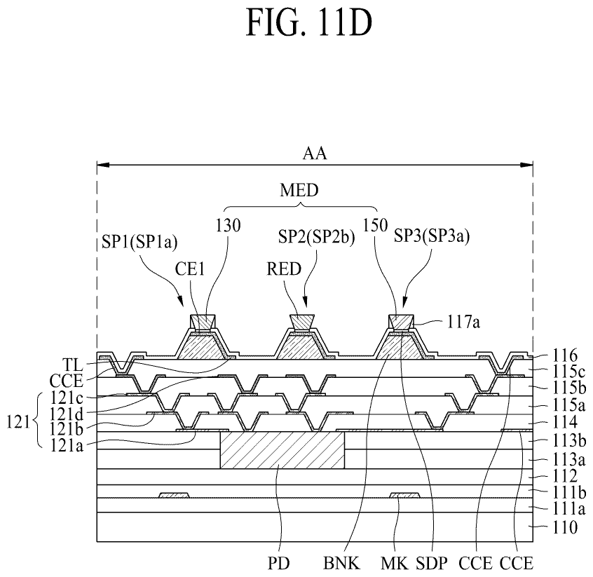

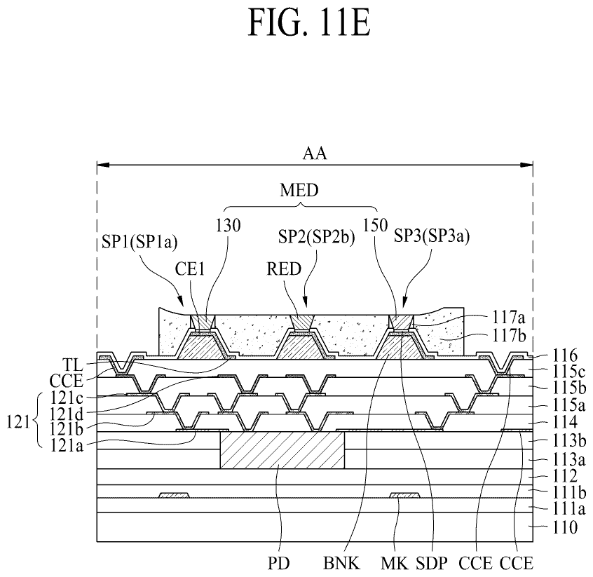

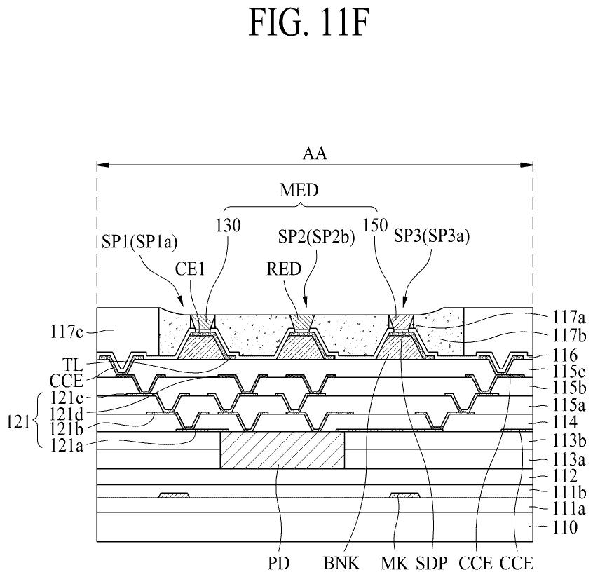

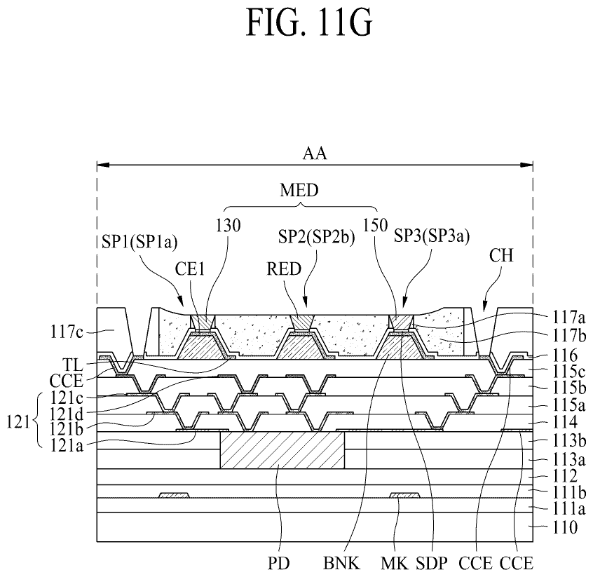

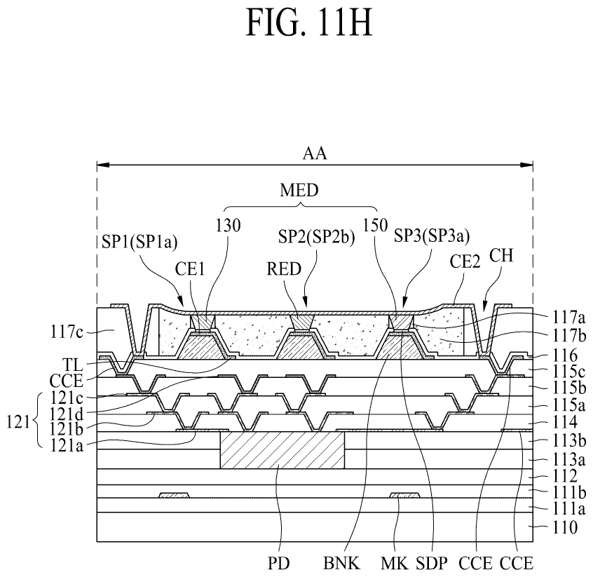

FIGS. 11A to 11H are process cross-sectional views illustrating a repair process of a light emitting diode according to an embodiment of the present disclosure.

The first main subpixel SPla of the first subpixel SP1 and the second blank subpixel SP2b of the second subpixel SP2, which are shown in FIGS. 11A to 11H, correspond to the first main subpixel SPla and the second blank subpixel SP2b, which are shown in FIGS. 6A and 6B. In more detail, the first main subpixel SPla of the first subpixel SP1 and the second blank subpixel SP2b of the second subpixel SP2, which are shown in FIGS. 11A to 11H, may correspond to the cross-sectional view of the first main subpixel SPla of the first subpixel SP1 and the second blank subpixel SP2b of the second subpixel SP2, which are shown in FIG. 10.

Referring to FIG. 11A, the first main light emitting diode 130 may be arranged in the first main subpixel SP1a of the first subpixel SP1, and the main light emitting diode may not be arranged in the second blank subpixel SP2b of the second subpixel SP2.

As described above, the first main subpixel SPla, the second main subpixel SP2a, and the third main subpixel SP3a are arranged in a zigzag shape.

The second electrode CE2 and the solder pattern SDP are arranged to be spaced apart from each other in the second blank subpixel SP2b of the second subpixel SP2. As a result, it is possible to prevent or reduce a current from flowing to the second electrode CE2.

Referring to FIG. 11A, a first optical layer 117a is arranged in an entire area of the first subpixel SP1 and the second subpixel SP2.

Referring to FIG. 11B, the second electrode CE2 is removed through wet etching. When the second electrode CE2 is removed through wet etching, the main light emitting diode MED and the first optical layer 117a may be exposed.

Referring to FIG. 11C, the first optical layer 117a exposed through wet etching is removed through dry etching. When the first optical layer 117a is removed through dry etching, the passivation layer 116 is exposed.

In this case, the first optical layer 117a may be arranged to cover the side of the first main light emitting diode 130. In detail, the entire area of the first optical layer 117a may overlap the main light emitting diode MED when viewed in a plan view.

Referring to FIG. 11D, the redundancy light emitting diode RED is additionally transferred to the second blank subpixel SP2b (see FIG. 10).

Referring to FIG. 11E, a second optical layer 117b may be formed in an area that overlaps the first subpixel SP1 and the second subpixel SP2. The description of the second optical layer 117b is repeated and thus will be omitted.

Referring to FIG. 11F, a third optical layer 117c may be formed on the passivation layer 116.

Referring to FIG. 11G, a contact hole CH passing through the third optical layer 117c may be formed.

Referring to FIG. 11H, the second electrode CE2 may be formed on the main light emitting diode MED and the redundancy light emitting diode RED.

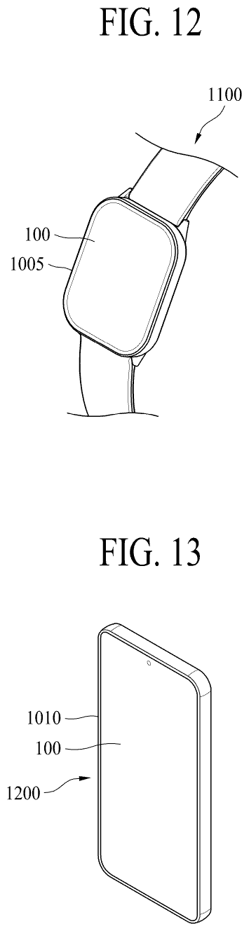

FIGS. 12 to 15 are views illustrating devices to which a display apparatus according to embodiments of the present disclosure is applied.

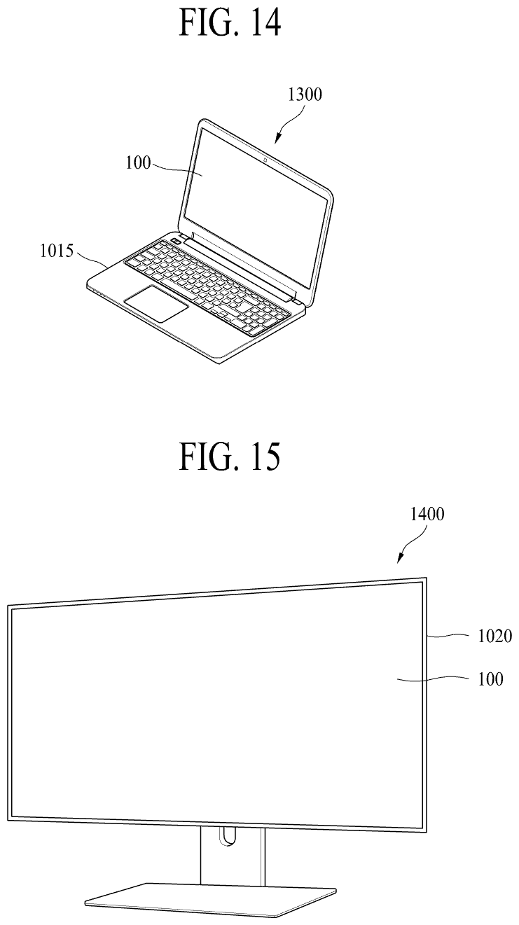

Referring to FIGS. 12 to 15, the display apparatus according to embodiments of the present disclosure may be included in various devices or electronic devices. For example, various electronic devices may include a wearable device 1100 as shown in FIG. 12, a mobile device 1200 as shown in FIG. 13, a notebook device 1Q as shown in FIG. 14, and a monitor or TV 1400 as shown in FIG. 15, but the embodiments of the present disclosure are not limited thereto.

Each of the wearable device 1100, the mobile device 1200, a laptop 1300, and the monitor or TV 1400 may respectively include a case unit 1005, 1010, 1015, or 1020 and a display panel 100 and a display apparatus 1000 according to the above-described embodiments of the present disclosure.

For example, the display apparatus according to an embodiment of the present disclosure may be applied to a mobile device, a video phone, a smart watch, a watch phone, a wearable apparatus, a foldable apparatus, a rollable apparatus, a bendable apparatus, a flexible apparatus, a curved apparatus, a sliding apparatus, a variable apparatus, an electronic notebook, an electronic book, a portable multimedia player (PMP), a personal digital assistant (PDA), an MP3 player, a mobile medical device, a desktop personal computer (PC), a laptop PC, a netbook computer, a workstation, a navigation device, a vehicle display, a theater display, a television, a wall paper device, a signage device, a signage device, a game device, a laptop device, a monitor, a camera, a camcorder, a home appliance, etc.

According to the present disclosure, the following advantageous effects may be obtained.

The display apparatus according to an embodiment of the present disclosure includes a smaller number of redundancy light emitting diodes, thereby reducing the manufacturing cost of the display apparatus.

It will be apparent to those skilled in the art that the present disclosure described above is not limited by the above-described embodiments and the accompanying drawings and that various substitutions, modifications and variations may be made in the present disclosure without departing from the spirit or scope of the disclosures. Consequently, the scope of the present disclosure is defined by the accompanying claims and it is intended that all variations or modifications derived from the meaning, scope and equivalent concept of the claims fall within the scope of the present disclosure.

What is claimed is:

1. A display apparatus comprising:
a substrate including a display area and a non-display area;
a pixel driving circuit in the display area of the substrate;
an insulating layer on the pixel driving circuit;
a main light emitting diode over the insulating layer; and
a first optical layer on a side of the main light emitting diode,
wherein an entire area of the first optical layer on a plane overlaps the main light emitting diode.

2. The display apparatus of claim 1, wherein the first optical layer surrounds the side of the main light emitting diode.

3. The display apparatus of claim 1, further comprising:
a second optical layer on one surface of the first optical layer,
wherein the first optical layer is between the second optical layer and the main light emitting diode.

4. The display apparatus of claim 3, wherein the first optical layer and the second optical layer include different materials.

5. The display apparatus of claim 4, wherein the first optical layer includes an organic insulating material and the second optical layer includes the organic insulating material and fine metal particles dispersed in the organic insulating material.

6. The display apparatus of claim 5, wherein the organic insulating material includes siloxane and the fine metal particles include titanium dioxide.

7. The display apparatus of claim 1, further comprising:
a bank on the insulating layer;
a first electrode between the main light emitting diode and the bank; and
a signal line on the insulating layer and electrically connecting the first electrode with the pixel driving circuit.

8. The display apparatus of claim 7, further comprising:
a passivation layer on the signal line,
wherein the first optical layer is between the passivation layer and the main light emitting diode.

9. The display apparatus of claim 3, further comprising:
a third optical layer on a side of the second optical layer;
a second electrode on the main light emitting diode, the second electrode electrically connected to the main light emitting diode;
a contact electrode on the insulating layer, the contact electrode electrically connecting the second electrode with the pixel driving circuit; and
a plurality of first connection lines electrically connected to each other through a contact hole in the insulating layer, the plurality of first connection lines electrically connecting the contact electrode with the pixel driving circuit,
wherein the second electrode is connected to the contact electrode through a contact hole provided in the third optical layer.

10. The display apparatus of claim 1, further comprising:
a second electrode on the main light emitting diode, the second electrode electrically connected to the main light emitting diode; and
a black matrix on the second electrode; and
a fourth optical layer between the second electrode and the black matrix,
wherein the black matrix is non-overlapping with the first optical layer.

11. The display apparatus of claim 10, further comprising:
a cover layer on the second electrode;
a polarizing layer on the cover layer; and
a cover member on the polarizing layer.

12. The display apparatus of claim 1, further comprising:
a pad electrode on the insulating layer in the non-display area; and
a plurality of second connection lines electrically connected to each other through a contact hole in the insulating layer, the plurality of second connection lines electrically connecting the pad electrode with the pixel driving circuit.

13. The display apparatus of claim 1, further comprising:
an encapsulation layer surrounding the main light emitting diode and disposed between the first optical layer and the side of the main light emitting diode.

14. The display apparatus of claim 13, wherein the encapsulation layer is a reflective layer.

15. A display apparatus comprising:
a display area;
a non-display area outside the display area; and
a plurality of pixels in the display area and arranged in a first direction,
wherein each of the plurality of pixels includes a first subpixel, a second subpixel, and a third subpixel, which are arranged sequentially along the first direction,
wherein the first subpixel includes a first main subpixel, the second subpixel includes a second main subpixel, the third subpixel includes a third main subpixel,
wherein the first main subpixel and the third main subpixel are arranged in a first row parallel with the first direction and the second main subpixel is arranged in a second row parallel with the first direction and different from the first row.

16. The display apparatus of claim 15, wherein the first subpixel includes a first blank subpixel arranged in a same column as the first main subpixel,
the second subpixel includes a second blank subpixel arranged in a same column as the second main subpixel, and
the third subpixel includes a third blank subpixel arranged in a same column as the third main subpixel.

17. The display apparatus of claim 16, wherein at least one of the first main subpixel, the second main subpixel, or the third main subpixel includes a main light emitting diode, and at least one of the first blank subpixel, the second blank subpixel, or the third blank subpixel includes a redundancy light emitting diode.

18. The display apparatus of claim 17, further comprising:
a first optical layer on a side of the main light emitting diode,
wherein an entire area of the first optical layer on a plane overlaps the main light emitting diode.

19. The display apparatus of claim 18, wherein the first optical layer is not arranged on a side of the redundancy light emitting diode.

20. The display apparatus of claim 17, wherein any one of the first main subpixel, the second main subpixel, and the third main subpixel includes a transfer defect, and the redundancy light emitting diode is arranged in a same column as the subpixel having the transfer defect.

21. The display apparatus of claim 17, further comprising:
a signal line electrically connected to the main light emitting diode and the redundancy light emitting diode, the signal line extended in a second direction perpendicular to the first direction.

22. The display apparatus of claim 21, wherein the plurality of pixels include N main subpixels and a sum of a number of main light emitting diodes and a number of redundancy light emitting diodes is N.

23. The display apparatus of claim 15, wherein the plurality of pixels include a first pixel and a second pixel, which are arranged in a second direction perpendicular to the first direction,
each of the first pixel and the second pixel includes a plurality of main light emitting diodes and further includes one second electrode electrically connected to the plurality of main light emitting diodes of the first pixel, and another second electrode electrically connected to the plurality of main light emitting diodes of the second pixel, and
the one second electrode and the other second electrode are spaced apart from each other based on an area between the first pixel and the second pixel.

24. The display apparatus of claim 15, wherein the non-display area includes a first non-display area surrounding the display area, a bending area extended from one side of the first non-display area, and a second non-display area extended from the bending area and in which a pad portion is arranged,
the non-display area includes a plurality of link lines extended from the pad portion of the second non-display area to the bending area and the first non-display area,
the display area includes a plurality of driving lines connected to the plurality of link lines, and
the plurality of driving lines are connected to a plurality of pixel driving circuits in the display area.

25. A display apparatus comprising:
a plurality of pixels in a display area of a substrate, each of the plurality of pixels including a first subpixel, a second subpixel, and a third subpixel, which are arranged sequentially along a first direction,
wherein the first subpixel includes a first main subpixel, the second subpixel includes a second main subpixel, the third subpixel includes a third main subpixel,
wherein the first main subpixel, the second main subpixel, and the third main subpixel are arranged in a zigzag shape,
wherein the plurality of pixels include N main subpixels and a sum of a number of light emitting diodes included in the plurality of pixels is N.
